(19) United States
(12) Patent Application Publication
(10) Pub. No.: US 2026/0215075 A1
(43) Pub. Date: Jul. 23, 2026

(54) Method For Manufacturing Light-Emitting Element, The Light-Emitting Element, And Electronic Apparatus Including The Light-Emitting Element

(71) Applicant: Samsung Display Co., Ltd., Yongin-si (KR)

(72) Inventors: Sungjae Kim, Yongin-si (KR); Youngsik Kim, Yongin-si (KR); Hongrae Kim, Yongin-si (KR); Juo Nam, Yongin-si (KR); Seung-Won Park, Yongin-si (KR); Bitna Yoon, Yongin-si (KR); Taekjoon Lee, Yongin-si (KR); Junehyuk Jung, Yongin-si (KR)

(73) Assignee: Samsung Display Co., Ltd., Yongin-si (KR)

(21) Appl. No.: 19/439,621

(22) Filed: Jan. 5, 2026

(30) Foreign Application Priority Data
Jan. 23, 2025 (KR) 10-2025-0010290

(51) Int. Cl. H10K 50/115; H10K 59/12; H10K 71/12

(52) U.S. Cl. CPC H10K 50/115; H10K 59/1201; H10K 71/12

(57) ABSTRACT

A method for manufacturing a light-emitting element may include forming an emission layer by providing a core, an intermediate layer covering the core, and a shell covering the intermediate layer. The core may include a multi-component-based compound including Cu, In, Ga, and S, and the intermediate layer may include Zn. The method for manufacturing a quantum dot may include preparing a first mixture including a copper precursor, an indium precursor, and a gallium precursor, providing a first sulfur precursor to form a preliminary core at a first temperature, cooling the preliminary core at a second temperature, providing a first zinc precursor to form a preliminary quantum dot including the core and the intermediate layer at the second temperature, and forming a shell. In the forming of the preliminary quantum dot, the intermediate layer may be formed by an in-situ process.

### CROSS-REFERENCE TO RELATED APPLICATIONS

This U.S. non-provisional patent application claims priority under 35 U.S.C. § 119 to Korean Patent Application No. 10-2025-0010290, filed on Jan. 23, 2025, the entire contents of which are hereby incorporated by reference.

### TECHNICAL FIELD

The present disclosure relates to a method for manufacturing a light-emitting element that includes providing a quantum dot, and a light-emitting element manufactured according to the manufacturing method, and an electronic apparatus including the light-emitting element.

### BACKGROUND

Quantum dots, which are semiconductor nanocrystals, may have different energy band gaps and emit light with various emission wavelengths by controlling the size and composition of the nanocrystals. In order to improve color reproductivity, quantum dot light-emitting elements using a quantum dot as an emission material are being developed. Quantum dots including a core and a shell have deterioration in color purity and material stability after forming the shell, and thus require improvements.

### SUMMARY

The present disclosure provides a method for manufacturing a light-emitting element, exhibiting excellent processibility.

The present disclosure also provides a light-emitting element emitting light with excellent color purity and an electronic apparatus including the same.

An aspect of the present disclosure provides a method for manufacturing a light-emitting element including preparing a first electrode, providing a quantum dot that includes a core, an intermediate layer covering the core, and a shell covering the intermediate layer to form an emission layer on the first electrode, forming a second electrode on the emission layer, forming a hole transport region, and forming an electron transport region. Any one among the forming of the hole transport region; and the forming of the electron transport region is performed between the preparing of the first electrode and the forming of the emission layer, and the other one is performed between the forming of the emission layer and the forming of the second electrode, the core includes a multi-component-based compound including Cu, In, Ga, and S, the intermediate layer includes Zn, the quantum dot is formed by a method for manufacturing a quantum dot. The method for manufacturing a quantum dot includes preparing a first mixture including a copper precursor, an indium precursor, and a gallium precursor, providing a first sulfur precursor to the first mixture to form a preliminary core at a first temperature, cooling the preliminary core at a second temperature lower than the first temperature, providing a first zinc precursor to the preliminary core to form a preliminary quantum dot including the core and the intermediate layer at a second temperature, and forming the shell covering the intermediate layer, and in the forming of the preliminary quantum dot, the intermediate layer is formed using an in-situ process.

In an aspect, the shell may include ZnS.

In an aspect, the second temperature may be about 20° C. to about 280° C.

In an aspect, when the second temperature is about 260° C. to about 280° C., the number of moles of the first zinc precursor provided may be about 0.01 times to about 4 times the number of moles of the gallium precursor.

In an aspect, when the second temperature is higher than about 200° C. and lower than about 260° C., the number of moles of the first zinc precursor provided may be more than about 4 times and about 36.90 times or less the number of moles of the gallium precursor.

In an aspect, when the second temperature is about 20° C. to about 200° C., the number of moles of the first zinc precursor provided may be about 0.01 times to about 73.90 times the number of moles of the gallium precursor.

In an aspect, the first zinc precursor may include at least one among dimethyl zinc, diethyl zinc, zinc acetate, zinc acetylacetonate, zinc iodide, zinc bromide, zinc chloride, zinc fluoride, zinc oleate, zinc carbonate, zinc cyanide, zinc nitrate, zinc oxide, zinc peroxide, zinc perchlorate, zinc sulfate, or zinc carboxylate.

In an aspect, the first temperature may be about 230° C. to about 330° C.

In an aspect, the first mixture may further include at least one of oleylamine, 1-octadecene, octadecane, methanethiol, ethanethiol, propanethiol, butanethiol, pentanethiol, hexanethiol, octanethiol, hexadecanethiol, benzylthiol, methane amine, ethane amine, propane amine, butylamine, pentylamine, hexylamine, octylamine, dodecylamine, hexadecylamine, octadecylamine, dimethylamine, diethylamine, dipropylamine, trioctylamine, methanoic acid, ethanoic acid, propanoic acid, buthanoic acid, pentanoic acid, hexanoic acid, heptanoic acid, octanoic acid, dodecanoic acid, hexadecanoic acid, octadecanoic acid, oleic acid, benzoic acid, trimethyl phosphine, methyldiphenyl phosphine, triethyl phosphine, ethyldiphenyl phosphine, trioctyl phosphine, trimethyl phosphine oxide, methyldiphenyl phosphine oxide, triethyl phosphine oxide, ethyldiphenyl phosphine oxide, or trioctyl phosphine oxide.

In an aspect, the first sulfur precursor may further include at least one of S-oleylamine, 1-dodecanethiol, trioctylphosphine-sulfur (TOP-S), S-tributylphosphine (S-TBP), S-triphenylphosphine (S-TPP), S-trioctylamine (S-TOA), S-octadecene (S-ODE), S-diphenylphosphine (S-DPP), S-dodecylamine, octanethiol, octadecanethiol, α-toluenethiol, allyl mercaptan, or bis(trimethylsilyl) sulfide.

In an aspect, the forming of the shell may include preparing a solvent containing tri-n-octylamine, providing the preliminary quantum dot, a second zinc precursor, and a second sulfur precursor to the solvent to form a second mixture, and heating to a third temperature to form the shell covering the intermediate layer.

In an aspect, the quantum dot may have a full width at half maximum (FWHM) less than about 50 nm and a quantum yield of 80% or greater.

In an aspect, the intermediate layer may further include sulfur derived from the first sulfur precursor.

In an aspect of the present disclosure, a light-emitting element includes a first electrode, an emission layer including a quantum dot that includes a core, an intermediate layer covering the core, and a shell covering the intermediate layer and disposed on the first electrode, a second electrode disposed on the emission layer, a hole transport region disposed between the first electrode and the second electrode, and an electron transport region disposed between the first electrode and the second electrode, wherein the emission layer is disposed between the hole transport region and the electron transport region, and wherein the core includes a multi-component-based compound including Cu, In, Ga, and S, the intermediate layer includes Zn, and the shell includes ZnS.

In an aspect, the quantum dot may have a full width at half maximum (FWHM) of less than about 50 nm and quantum yield of about 80% or more.

In an aspect, the shell has a thickness of about 0.1 nm to about 2 nm.

In an aspect, the shell may further include at least one of SiO₂, Al₂O₃, TiO₂, ZnO, MnO, Mn₂O₃, Mn₃O₄, CuO, FeO, Fe₂O₃, Fe₃O₄, CoO, Co₃O₄, NiO, MgAl₂O₄, CoFe₂O₄, NiFe₂O₄, CoMn₂O₄, ZnSe, ZnTe, ZnSeS, ZnTeS, ZnGaS, GaAs, GaP, GaS, GaSe, AgGaS, AgGaS₂, GaSb, HgS, HgSe, HgTe, InAs, InP, InGaP, InSb, AlAs, AlP, or AlSb.

In an aspect of the present disclosure, an electronic apparatus includes a display module providing an image. The display module includes a base layer, a circuit layer disposed on the base layer, and a display element layer including a light-emitting element and disposed on the circuit layer. The light-emitting element includes a first electrode, an emission layer including a quantum dot that includes a core, an intermediate layer covering the core, and a shell covering the intermediate layer, and disposed on the first electrode, a second electrode disposed on the emission layer, a hole transport region disposed between the first electrode and the second electrode, and an electron transport region disposed between the first electrode and the second electrode, wherein the emission layer is disposed between the hole transport region and the electron transport region, and the core includes a multi-component-based compound including Cu, In, Ga, and S, the intermediate layer includes Zn, and the shell includes ZnS.

In an aspect, the quantum dot may have a full width half maximum of less than about 50 nm and quantum yield of about 80% or more.

In an aspect, the shell further may include at least one of SiO₂, Al₂O₃, TiO₂, ZnO, MnO, Mn₂O₃, Mn₃O₄, CuO, FeO, Fe₂O₃, Fe₃O₄, CoO, Co₃O₄, NiO, MgAl₂O₄, CoFe₂O₄, NiFe₂O₄, CoMn₂O₄, ZnSe, ZnTe, ZnSeS, ZnTeS, ZnGaS, GaAs, GaP, GaS, GaSe, AgGaS, AgGaS₂, GaSb, HgS, HgSe, HgTe, InAs, InP, InGaP, InSb, AlAs, AlP, or AlSb.

### BRIEF DESCRIPTION OF THE DRAWINGS

The accompanying drawings are included to provide a further understanding of the present disclosure, and are incorporated in and constitute a part of this specification. The drawings illustrate aspects of the present disclosure and, together with the description, serve to explain principles of the present disclosure. In the drawings:

FIG. 1 is a perspective view illustrating an electronic apparatus according to an aspect;

FIG. 2 is a block diagram of an electronic apparatus according to an aspect;

FIG. 3 is a view illustrating electronic apparatuses according to various aspects;

FIG. 4 is an exploded perspective view illustrating an electronic apparatus according to an aspect;

FIG. 5 is a cross-sectional view illustrating a portion taken along line I-I′ in FIG. 4;

FIG. 6 is a plan view illustrating a portion of an electronic apparatus according to an aspect;

FIG. 7A is a cross-sectional view illustrating a portion of an electronic apparatus according to an aspect;

FIG. 7B is a cross-sectional view illustrating a portion of an electronic apparatus according to an aspect;

FIG. 8A is a cross-sectional view illustrating a light-emitting element according to an aspect;

FIG. 8B is a cross-sectional view illustrating a light-emitting element according to an aspect;

FIG. 8C is a cross-sectional view illustrating a light-emitting element according to an aspect;

FIG. 8D is a cross-sectional view illustrating a light-emitting element according to an aspect;

FIG. 9 is a view schematically illustrating a quantum dot according to an aspect;

FIG. 10A is a flow chart showing a method for manufacturing a light-emitting element, according to an aspect;

FIG. 10B is a flow chart showing a method for manufacturing a light-emitting element, according to an aspect;

FIG. 10C is a flow chart showing a method for manufacturing a light-emitting element, according to an aspect;

FIG. 11 is a diagram schematically showing processes of manufacturing a light-emitting element, according to an aspect;

FIG. 12A is a graph showing PL spectra on quantum dots;

FIG. 12B is a graph showing PL spectra on quantum dots;

FIG. 13A is a graph showing PL spectra on quantum dots;

FIG. 13B is a graph showing PL spectra on quantum dots;

FIG. 13C is a graph showing PL spectra on quantum dots; and

FIG. 14 is a graph showing a color coordinate of a quantum dot.

### DETAILED DESCRIPTION

In the present disclosure, various modifications may be made, various forms may be applied, and specific aspects will be illustrated in the drawings and described in detail in the text. However, this is not intended to limit the present disclosure to a specific disclosed form, and it should be understood to include all changes, equivalents, and substitutes included in the spirit and scope of the present disclosure.

As used herein, when a component (or a region, a layer, a part, etc.) is referred to as being “on”, “connected to”, or “bonded to” other components, it can be directly “disposed/connected to/bonded to” the other component, or a third intervening component may also be present therebetween.

Like reference numerals and symbols refer to like elements. In addition, in the drawings, the thickness, the ratio, and the dimensions of elements are exaggerated for an effective description of technical contents. The term “and/or,” includes all combinations of one or more of which associated configurations may be defined.

It will be understood that, although the terms first, second, etc. may be used herein to describe various elements, these elements should not be limited by these terms. These terms are only used to distinguish one element, component, region, layer or part from another element, component, region, layer or part. For example, a first element, a first component, a first region, a first layer, or a first part may be referred to as a second element, a second component, a second region, a second layer, or a second part and similarly, a second element, a second component, a second region, a second layer, or a second part also may be referred to as a first element, a first component, a first region, a first layer, or a first part. The singular expressions are intended to include the plural expressions as well, unless the context clearly indicates otherwise.

Also, the terms such as “below”, “on the lower side”, “above”, and “on the upper side” may be used to describe the relationships of the components shown in the drawings. The terms are used as a relative concept and are described with reference to the direction indicated in the drawings.

It should be understood that the terms such as “include”, and “have” are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the present disclosure pertains. Also, terms, such as those defined in commonly used dictionaries, should be interpreted as having a meaning that is consistent with their meaning in the context of the relevant art and should not be interpreted in an idealized or overly formal sense unless expressly so defined herein.

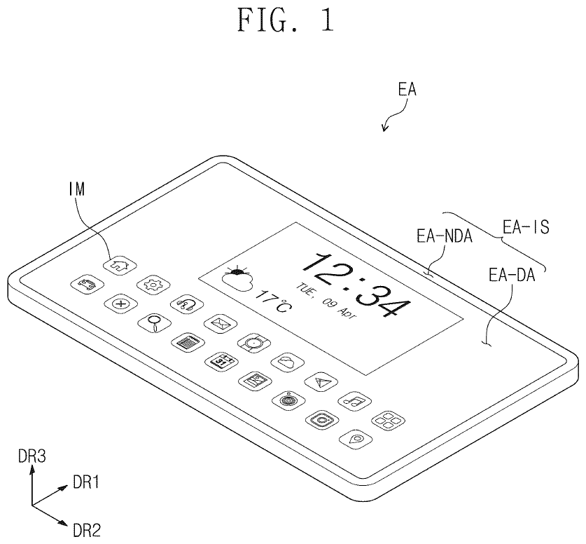

Hereinafter, aspects according to the present disclosure will be described with reference to the accompanying drawings. FIG. 1 is a perspective view illustrating an electronic apparatus according to an aspect.

The electronic apparatus EA according to an aspect illustrated in FIG. 1 may be a device activated in response to an electrical signal. For example, the electronic apparatus EA may be a personal computer, a laptop computer, a personal digital terminal, a game console, a portable electronic apparatus, a television, a monitor, an outdoor billboard, a car navigation system, or a wearable device, but aspects of the present disclosure are not limited thereto. In FIG. 1, the portable electronic apparatus is exemplified as an electronic apparatus EA.

The electronic apparatus EA may provide an image IM to a user through a display surface EA-IS. The display surface EA-IS may be parallel to a surface defined by a first direction axis DR1 and a second direction axis DR2. The electronic apparatus EA may display an image IM toward a third direction axis DR3. The image IM may include a still image as well as a dynamic image. FIG. 1 illustrates the electronic apparatus EA equipped with a flat display surface EA-IS, but an aspect is not limited thereto. For example, the electronic apparatus EA may include a curved display surface or a 3-dimensional display surface. The 3-dimensional display surface may include a plurality of display regions indicating different directions from each other.

Directions indicated by first to third direction axes DR1, DR2, and DR3, which are described in the present specification, are relative concepts, and may be converted to other directions. In addition, the directions indicated by the first to third direction axes DR1, DR2, and DR3 may be described as the first to third directions, and same reference numerals may be used.

In the present specification, the first direction axis DR1 and the second direction axis DR2 may be perpendicular to each other, and the third direction axis DR3 is in a normal direction to a plane defined by the first direction axis DR1 and the second direction axis DR2. A thickness direction of the electronic apparatus EA may be a parallel direction with the third direction axis DR3. The thickness direction of the electronic apparatus EA may use the same reference numeral with the third direction axis DR3. A front surface (or top surface) and a rear surface (or bottom surface) may be opposing to each other in the third direction axis DR3, and each normal direction of the front surface (or top surface) and the rear surface (or bottom surface) may be parallel to the third direction axis DR3. The front surface (or top surface) refers to an adjacent surface to the display surface EA-IS, and the rear surface (or bottom surface) refers to a surface spaced apart from the display surface EA-IS. An Upper side refers to a direction getting closer to the display surface EA-IS, and a lower side refers to a direction getting farther from the display surface EA-IS.

As used herein, a cross-section refers to a surface parallel to the thickness direction DR3. A plane refers to a surface which is perpendicular to the thickness direction DR3, and parallel to the plane defined by the first direction axis DR1 and the second direction axis DR2.

As used herein, overlapping of an element with another element means overlapping on a plane. In addition, overlapping of an element with another element is not limited to a case where the elements have the identical area and identical shape, but includes cases where they have different areas and/or different shapes.

The electronic apparatus EA may sense an external input applied from the outside. The external input may include input in various forms which are provided from the outside of the electronic apparatus EA. For example, the external input may include an external input applied to the electronic apparatus EA in close range or at a setting distance (for example, hovering) as well as a touch by a body part such as a user's hand. In addition, the external input may have various forms such as force, pressure, temperature, light.

The display surface EA-IS may include a display region EA-DA and a non-display region EA-NDA. The electronic apparatus EA may display an image IM through the display region EA-DA.

The display region EA-DA may be a region activated in response to an electronic signal. The display region EA-DA may be a region displaying an image IM and sensing external input in various forms.

The display region EA-DA may include the plane defined by the first direction axis DR1 and the second direction axis DR2. Unlike what is illustrated, the display region EA-DA may also include a curved surface that is bent from at least one side of the surface defined by the first direction axis DR1 and the second direction axis DR2. For example, the display region EA-DA may further include at least two curved surfaces, each bent from two sides of the plane defined by the first direction axis DR1 and the second direction axis DR2. For example, the display region EA-DA may further include four curved surfaces respectively bent from the four sides of the plane defined by the first direction axis DR1 and the second direction axis DR2.

The electronic apparatus EA according to an aspect may be flexible. The term “flexible” refers to properties of being bendable and can encompass everything from a structure that is capable of being completely folded to a structure that is capable of bending at a nanometer scale. For example, the electronic apparatus EA may be a rigid apparatus. Unlike what is described above, the electronic apparatus EA may be a foldable apparatus.

The non-display region EA-NDA may not be transparent and may have a color. The non-display region EA-NDA may be a region adjacent to the display region EA-DA. The non-display region EA-NDA may surround the display region EA-DA. Therefore, a shape of the display region EA-DA may be defined by the non-display region EA-NDA. However, FIG. 1 is illustrated for illustrative purposes, the non-display region EA-NDA may be disposed adjacent to only one side of the display region EA-DA or may be omitted. The display region EA-DA may be provided in various shapes and is not limited to any one aspect.

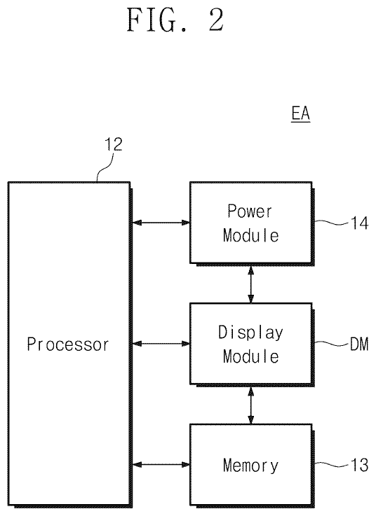

FIG. 2 is a block diagram of an electronic apparatus according to an aspect. Referring to FIG. 2, the electronic apparatus EA according to an aspect may include a display module DM, a processor 12, a memory 13, and a power module 14. As used herein, the electronic apparatus EA may be a display device or may include a display device. The display device may include a display module DM.

The processor 12 may include at least one among a central processing unit (CPU), an application processor (AP), a graphic processing unit (GPU), a communication processor (CP), an image signal processor (ISP), or a controller. The power module 14 may include a power supply module such as a power adapter or battery device, and a power conversion module that converts the supplied power by the power supply module to generate power needed for operations of the electronic apparatus EA.

In the memory 13, data information needed for an operation of the processor 12 or the display module DM may be stored. When the processor 12 executes an application stored in memory 13, a video data signal and/or input control signal may be transmitted to the display module DM, and the display module DM may process the provided signal to output the video information through a display screen.

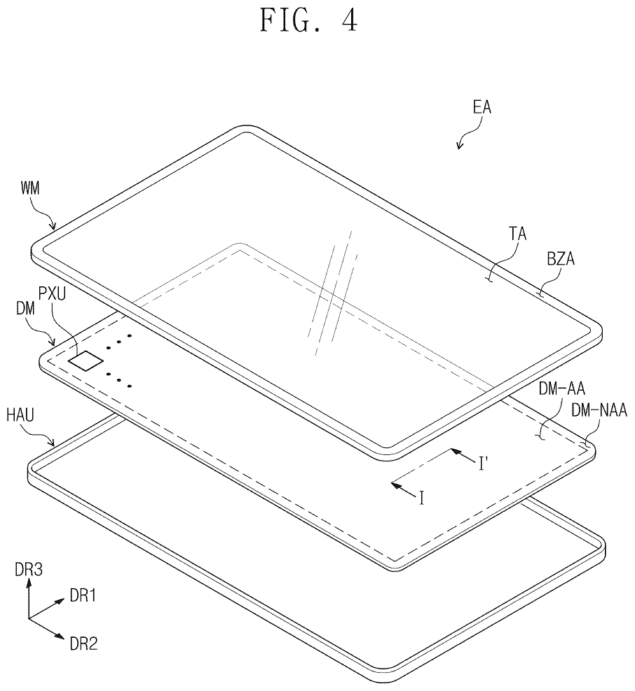

At least one among components of the electronic apparatus EA may be included in the display module DM (FIG. 4) according to an aspect. In addition, some components among independent modules functionally included in one module among the components of the electronic apparatus EA may be included in the display device, and some other components may be provided separately from the display device. For example, the display device may include a display module DM, and a processor 12, a memory 13, and a power module 14 may be provided in the other device forms in the electronic apparatus EA other than the display device.

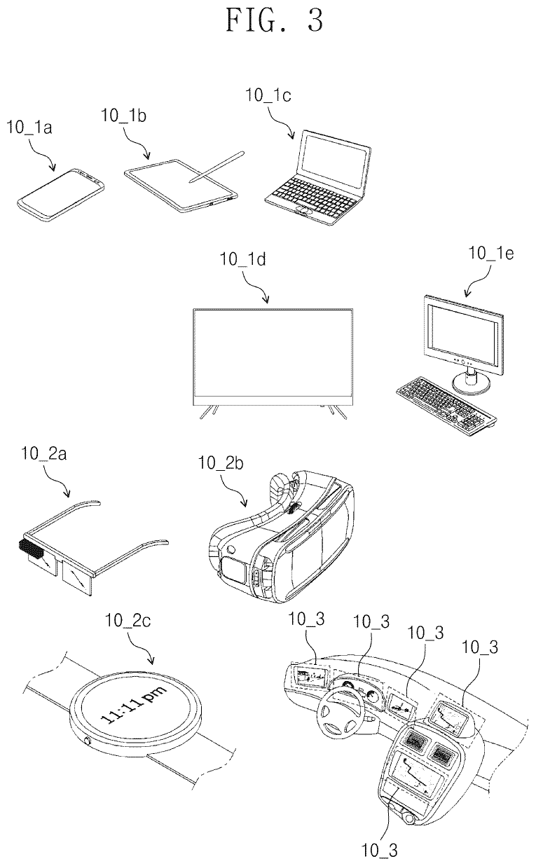

FIG. 3 is a schematic view illustrating electronic apparatuses according to various aspects. Referring to FIG. 3, an electronic apparatus including the display module DM (FIG. 4) according to an aspect may not include only an electronic apparatus for displaying an image such as a smart phone 10_1a, a tablet PC 10_1b, a laptop computer 10_1c, a TV 10_1d, and a desktop monitor 10_1e, but also include an wearable electronic apparatus including a display device such as smart glasses 10_2a, a head mount display 10_2b, a smart watch 10_2c, an electronic apparatus 10_3 for vehicles including a display device such as a center information display (CID) located on a vehicle's instrument cluster, center fascia, or dashboard, and a room mirror display, etc.

FIG. 4 is an exploded perspective view illustrating an electronic apparatus according to an aspect. Referring to FIG. 4, the electronic apparatus EA may include a display module DM. In addition, the electronic apparatus EA may further include a window member WM, and a housing HAU.

The window member WM may be disposed on the display module DM. The window member WM may cover an entire exterior of the electronic apparatus EA. The window member WM may include a transmission region TA, and a bezel region BZA. A front surface of the window member WM including the transmission region TA and the bezel region BZA may correspond to the front surface of the electronic apparatus EA. The transmission region TA may correspond to the display region EA-DA of the electronic apparatus EA illustrated in FIG. 1, and the bezel region BZA may correspond to the non-display region EA-NDA of the electronic apparatus EA illustrated in FIG. 1.

The transmission region TA may be an optically transparent region. The bezel region BZA may be a region having relatively lower light transmittance than the transmission region TA. The bezel region BZA may not be transparent and may have a color. The bezel region BZA may be adjacent to the transmission region TA and surround the transmission region TA. The bezel region BZA may define a shape of the transmission region TA. However, an aspect is not limited to what is illustrated, the bezel region BZA may be located adjacent to one side of the transmission region TA, and a portion thereof may be omitted.

The housing HAU may include a material having relatively high rigidity. For example, the housing HAU may include a frame and/or a plate composed of glass, plastic, or metal. A plurality of frames and/or plates may be provided. The housing HAU may provide an accommodating space. The display module DM may be accommodated in the accommodating space to be protected from external impact.

The display module DM may be activated in response to an electrical signal to provide a video image IM (FIG. 1). The display module DM may be activated and display a video image IM (or image, FIG. 1) in the display region EA-DA (FIG. 1) of the electronic apparatus EA. In the display module DM, an active region DM-AA and a peripheral region DM-NAA may be defined.

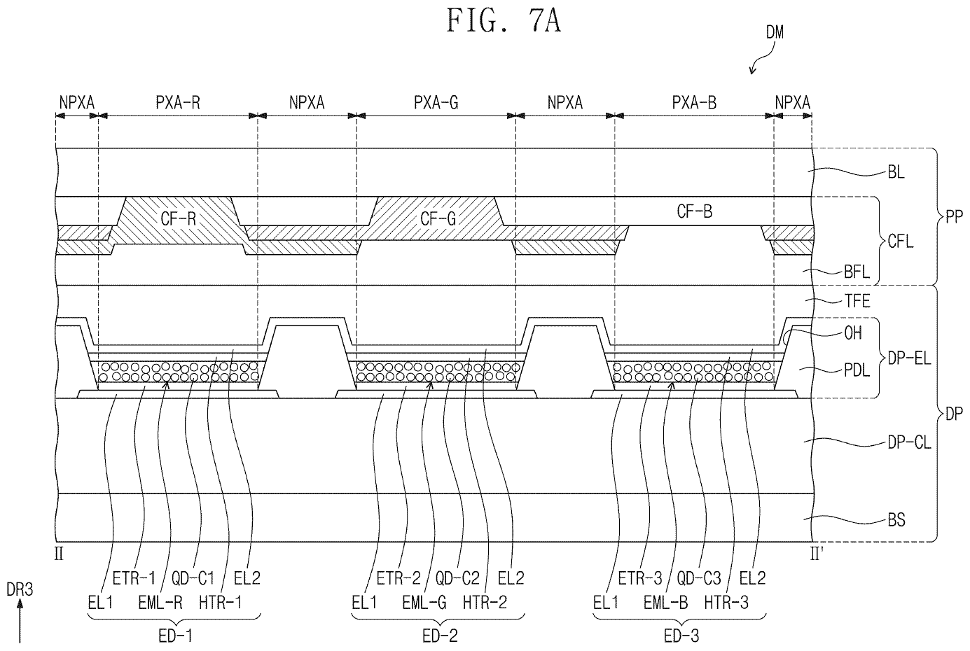

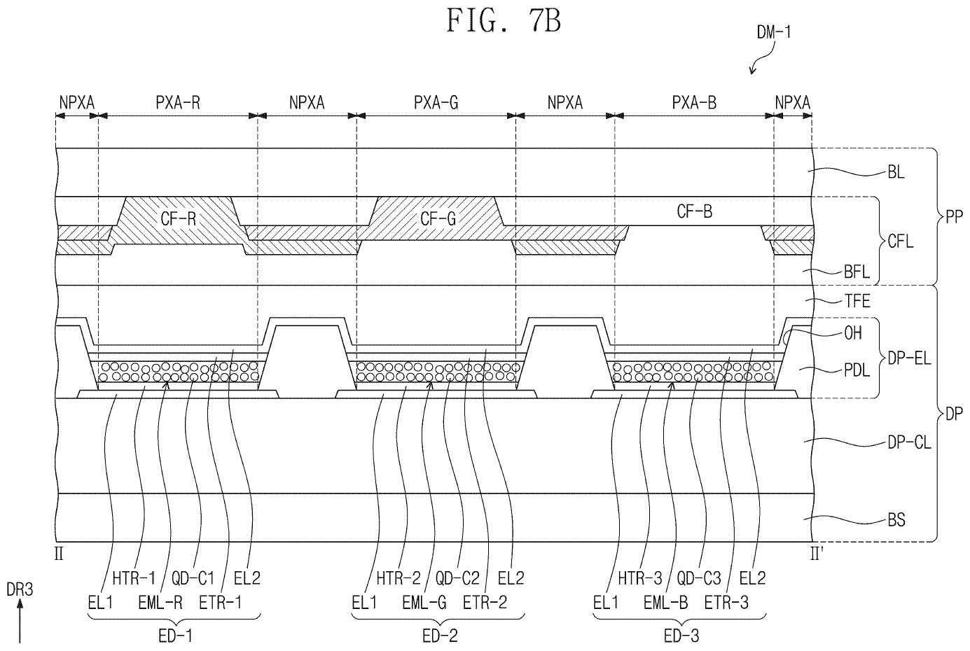

The active region DM-AA may be a region activated in response to an electrical signal. In the active region DM-AA, a unit pixel PXU may be disposed. A pixel may include a transistor (not illustrated) and light-emitting elements ED-1, ED-2, and ED-3 (FIG. 7A and FIG. 7B). The peripheral region DM-NAA may be a region positioned adjacent to at least one side of the active region DM-AA. In the peripheral region DM-NAA, a circuit, a line, and the like for driving the active region DM-AA may be positioned.

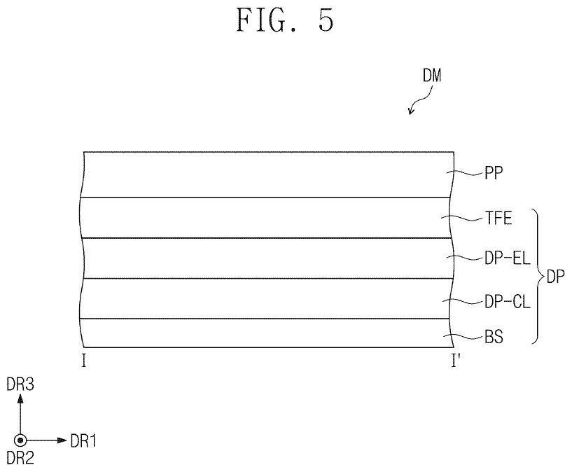

FIG. 5 is a cross-sectional view illustrating a portion taken along line I-I′ in FIG. 4. FIG. 5 may be a cross-sectional view illustrating a display module DM according to an aspect.

The display module DM may include a display panel DP and an optical layer PP disposed on the display panel DP. The display panel DP may include a base layer BS, a circuit layer DP-CL disposed on the base layer BS, a display element layer DP-EL disposed on the circuit layer DP-CL, and an encapsulation layer TFE disposed on the display element layer DP-EL.

The display panel DP may be a component substantially generating a video image. The display panel DP may be a luminous-type display panel. For example, the display panel may be a quantum dot light-emitting display panel including a quantum dot light-emitting element.

The base layer BS may be a member providing a base surface in which a circuit layer DP-CL is disposed. The base layer BS may be a rigid substrate or flexible substrate that is bendable, foldable, rollable, and the like. The base layer BS may be a glass substrate, a metal substrate, a polymer substrate, or the like. However, aspects of the present disclosure are not limited thereto, and the base layer BS may be an inorganic layer, an organic layer, or a composite material layer.

The circuit layer DP-CL may be disposed on the base layer BS. The circuit layer DP-CL may include an insulating layer, a semiconductor pattern, a conductive pattern, a signal line, etc. The insulating layer, the semiconductor layer, and the conductive layer are formed on the base layer BS, and then the insulating layer, the semiconductor layer, and the conductive layer may be selectively patterned through multiple photolithography processes. Thereafter, the semiconductor pattern, the conductive pattern, and the signal line included in the circuit layer DP-CL may be formed.

The display element layer DP-EL may be disposed on the circuit layer DP-CL. The display element layer DP-EL may include a pixel definition film PDL (FIG. 7A and FIG. 7B) and first to third light-emitting elements ED-1, ED-2, and ED-3 (FIG. 7A and FIG. 7B), which will be described later. For example, the display element layer DP-EL may include an organic emission material, an inorganic emission material, an organic-inorganic emission material, a quantum dot, or a quantum rod. For example, the display element layer DP-EL may include a micro LED, or a nano LED. More specifically, the display element layer DP-EL may include a quantum dot.

The encapsulation layer TFE may protect the display element layer DP-EL from moisture, oxygen, and a foreign substance such as dust particles. The encapsulation layer TFE may include at least one inorganic layer. The encapsulation layer TFE may include a structure in which an inorganic layer, an organic layer, and an inorganic layer are sequentially stacked.

The optical layer PP may be disposed on the display panel DP to thereby control, on the display panel DP, reflected light due to external light. The optical layer PP may include, for example, a polarization layer, or a color filter layer. Unlike what is illustrated in the drawings, the optical layer PP may be omitted.

Although not illustrated, the display module DM may further include an input sensing layer disposed between the display panel DP and the optical layer PP. The input sensing layer may sense external input and convert into a certain input signal and provide the input signal to the display panel DP. For example, the input sensing layer may be a touch sensing layer that senses a touch. The input sensing layer may recognize direct touch by a user, indirect touch by a user, direct touch by an object, or indirect touch by an object.

The input sensing layer may sense at least one among a location of the touch, and intensity (pressure) of the touch, applied from the outside. In an aspect, the input sensing layer may have various structures, or be composed of various materials, but is not limited to any one aspect. For example, the input sensing layer may sense external input by a capacitive method. The display panel DP may be provided with an input signal from the input sensing layer and may generate a video image corresponding to the input signal.

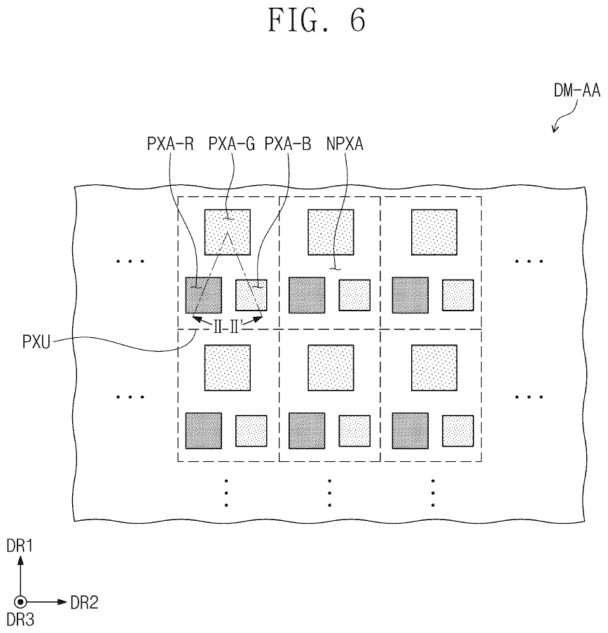

FIG. 6 is a plan view schematically illustrating an active region DM-AA according to an aspect. In FIG. 6, a plane including three pixel regions PXA-R, PXA-G, and PXA-B, and a light-blocking region NPXA is illustrated for illustrative purposes. A unit pixel PXU may include the three pixel regions PXA-R, PXA-G, and PXA-B, and the light-blocking region NPXA. The unit pixel PXU may be repeatedly disposed in the entire active region DM-AA illustrated in FIG. 4.

The light-blocking region NPXA may be disposed around the first to third pixel regions PXA-R, PXA-G, and PXA-B. The light-blocking region NPXA may define boundaries of the first to third pixel regions PXA-R, PXA-G, and PXA-B. The light-blocking region NPXA may surround the first to third pixel regions PXA-R, PXA-G, and PXA-B. In the light-blocking region NPXA, a structure preventing the first to third pixel regions PXA-R, PXA-G, and PXA-B from color mixing, for example, the pixel definition film PDL (FIG. 7A and FIG. 7B) and the like may be disposed.

The pixel regions PXA-R, PXA-G, and PXA-B may each be a region emitting light generated in the light-emitting elements ED-1, ED-2, and ED-3. In FIG. 6, the first to third pixel regions PXA-R, PXA-G, and PXA-B are illustrated to have the same shape on a plane, and have different areas on the plane, but aspects of the present disclosure are not limited thereto. At least two pixel regions among the first to third pixel regions PXA-R, PXA-G, and PXA-B may have the same area. Each area of the first to third pixel regions PXA-R, PXA-G, and PXA-B may be defined depending on a color of light emitted. The area of the pixel region emitting blue light among primary colors may be the smallest. The area may mean an area on the plane.

FIG. 6 illustrates that each of the first to third pixel regions PXA-R, PXA-G, and PXA-B, has a rectangular shape on a plane. Unlike this, each of the first to third pixel regions PXA-R, PXA-G, and PXA-B may have a different polygonal shape such as a rhombus or pentagon. Alternatively, each of the first to third pixel regions PXA-R, PXA-G, and PXA-B may have a rectangular shape of which a corner region is round. Meanwhile, the first to third pixel regions PXA-R, PXA-G, and PXA-B may have a different shape on the plane.

FIG. 6 illustrates that the second pixel region PXA-G is arranged in a first row, the first pixel region PXA-R and the third pixel region PXA-B are arranged in a second row. However, this is for illustrative purposes, and arrangements of the first to third pixel regions PXA-R, PXA-G, and PXA-B may be variously changed. For example, the first to third pixel regions PXA-R, PXA-G, and PXA-B may be arranged in the same low.

Any one among the first to third pixel regions PXA-R, PXA-G, and PXA-B may emit first light, another may emit second light different from the first light, and the remaining one may emit third light different from the first light and the second light. For example, the first pixel region PXA-R may emit red light, the second pixel region PXA-G may emit green light, and the third pixel region PXA-B may emit blue light. The first pixel region PXA-R may be referred to as a red pixel region, the second pixel region PXA-G may be referred to as a green pixel region, and third pixel region PXA-B may be referred to as a blue pixel region.

FIG. 7A is a cross-sectional view illustrating a portion taken along line II-II′ in FIG. 6. FIG. 7A may be a cross-sectional view specifically illustrating a constitution of a display module DM according to an aspect.

Referring to FIG. 7A, the base layer BS may include a single layer or multilayer. For example, the base layer BS may include a three-layered structure of a polymer resin layer, an adhesive layer, and a polymer resin layer. For example, the polymer resin layer may include a polyimide-based resin. In addition, the polymer resin layer may include at least one among an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. As used herein, a “~~”-based resin means including a “~~” functional group. For example, the polyimide-based resin means including a polyimide functional group.

The circuit layer DP-CL may include an insulating layer, a semiconductor layer, a conductive pattern, a signal line, etc. The circuit layer DP-CL may include a plurality of transistors (not illustrated). The transistors (not illustrated) may each include a control electrode, an input electrode, and an output electrode. For example, the circuit layer DP-CL may include a switching transistor, and a driving transistor for driving the light-emitting elements ED-1, ED-2, and ED-3 of the display element layer DP-EL.

The display element layer DP-EL may include the first to third light-emitting elements ED-1, ED-2, and ED-3, and the pixel definition film PDL. In the pixel definition film PDL, an opening OH may be defined.

The pixel definition film PDL may define the pixel regions PXA-R, PXA-G, and PXA-B. The pixel regions PXA-R, PXA-G, and PXA-B and the light-blocking region NPXA may be divided by the pixel definition film PDL.

The pixel definition film PDL may be formed using a polymer resin. For example, the pixel definition film PDL may be formed including a polyacrylate-based resin, or a polyimide-based resin. In addition, the pixel definition film PDL may be formed further including an inorganic material in addition to a polymer resin. Meanwhile, the pixel definition film PDL may be formed by including a light-absorbing material or may be formed by including a black pigment, or black dye. The pixel definition film PDL formed by including the black pigment or black dye may implement a black pixel definition film. During the forming of the pixel definition film PDL, carbon black and the like may be used as the black pigment or black dye, but an embodiment is not limited thereto.

In addition, the pixel definition film PDL may be formed using an inorganic material. For example, the pixel definition film PDL may be formed using an inorganic material such as silicon nitride (SiNₓ), silicon oxide (SiOₓ), or silicon oxynitride (SiOₓN_{y}).

Each of the light-emitting elements ED-1, ED-2, and ED-3 may include first electrode EL1, emission layers EML-R, EML-G, and EML-B disposed on the first electrode EL1, a second electrode EL2 disposed on the emission layers EML-R, EML-G, and EML-B, hole transport regions HTR-1, HTR-2, and HTR-3 disposed between the first electrode EL1 and the second electrode EL2, and electron transport regions ETR-1, ETR-2, and ETR-3 disposed between the first electrode EL1 and the second electrode EL2. The emission layers EML-R, EML-G, and EML-B may be disposed between the electron transport regions ETR-1, ETR-2, and ETR-3 and the hole transport regions HTR-1, HTR-2, and HTR-3.

Each of the emission layers EML-R, EML-G, and EML-B may include a first electrode EL1, electron transport regions ETR-1, ETR-2, and ETR-3, disposed on the first electrode EL1, emission layers EML-R, EML-G, and EML-B, disposed on the electron transport regions ETR-1, ETR-2, and ETR-3, hole transport regions HTR-1, HTR-2, and HTR-3 disposed on the emission layers EML-R, EML-G, and EML-B, and a second electrode EL2 disposed on the hole transport regions HTR-1, HTR-2, and HTR-3. The electron transport regions ETR-1, ETR-2, and ETR-3 may be disposed between the first electrode EL1 and the emission layer EML-R, EML-G, and EML-B, and the hole transport regions HTR-1, HTR-2, and HTR-3 may be disposed between the emission layers EML-R, EML-G, and EML-B and the second electrode EL2.

At least a portion of the first electrode EL1 may be exposed in the opening OH of the pixel definition film PDL. The first electrode EL1 may have conductivity. The first electrode EL1 may be formed using a metal material, a metal alloy, or a conductive compound. The first electrode EL1 may be a cathode, or anode. However, aspects of the present disclosure are not limited thereto. In addition, the first electrode EL1 may be a pixel electrode. The first electrode EL1 may be a transmissive electrode, a transflective electrode, or a reflective electrode. The first electrode EL1 may include at least one selected from Ag, Mg, Cu, Al, Pt, Pd, Au, Ni, Nd, Ir, Cr, Li, Ca, LiF, Mo, Ti, W, In, Sn, or Zn, a compound of two or more selected therefrom, a mixture two or more selected therefrom, or an oxide thereof.

When the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). When the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound or mixture thereof (e.g., a mixture of Ag and Mg). Alternatively, the first electrode EL1 may have a multi-layered structure including a reflective or transflective layer formed using the above-described materials, and a transparent conductive layer formed using indium tin oxide (ITO), indium zinc oxide (IZO), zinc oxide (ZnO), indium tin zinc oxide (ITZO), etc. For example, the first electrode EL1 may have a three-layered structure of ITO/Ag/ITO, but is not limited thereto. In addition, the first electrode EL1 may include the above-described metal materials, a combination of two or more metal materials selected from among the above-described metal materials, an oxide of the above-described metal materials, etc., but an embodiment is not limited thereto. The first electrode EL1 may have a thickness of about 700 Å to about 10000 Å. For example, the first electrode EL1 may have the thickness of about 1000 Å to about 3000 Å.

The second electrode EL2 may be a common electrode. The second electrode EL2 may be an anode, or cathode, but aspects of the present disclosure are not limited thereto. For example, when the first electrode EL1 is an anode, the second electrode EL2 may be a cathode, and when the first electrode EL1 is a cathode, the second electrode EL2 may be an anode. The second electrode EL2 may include at least one selected from Ag, Mg, Cu, Al, Pt, Pd, Au, Ni, Nd, Ir, Cr, Li, Ca, LiF, Mo, Ti, W, In, Sn, or Zn, a compound of two or more selected therefrom, a mixture of two or more selected therefrom, or an oxide thereof.

The second electrode EL2 may be a transmissive electrode, a transflective electrode, or a reflective electrode. When the second electrode EL2 is a transmissive electrode, the second electrode EL2 may be formed using a transparent metal oxide such as indium tin oxide (ITO), indium zinc oxide (IZO), zinc oxide (ZnO), or indium tin zinc oxide (ITZO).

When the second electrode EL2 is a transflective electrode or reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or a compound or mixture including the same (for example, AgMg, AgYb, or MgYb). Alternatively, the second electrode EL2 may have a multi-layered structure including a reflective or transflective layer formed using the above-described materials, or a transparent conductive layer formed using indium tin oxide (ITO), indium zinc oxide (IZO), zinc oxide (ZnO), indium tin zinc oxide (ITZO), etc. For example, the second electrode EL2 may include the above-described metal materials, combinations of two or more metal materials selected from the above-described metal materials, or an oxide of the above-described metal materials.

Although not illustrated, the second electrode EL2 may be connected to an auxiliary electrode. If the second electrode EL2 is connected to the auxiliary electrode, resistance of the second electrode EL2 may decrease.

The emission layers EML-R, EML-G, and EML-B may be disposed between the first electrode EL1 and the second electrode EL2. The first light-emitting element ED-1 may include the first emission layer EML-R, the second light-emitting element ED-2 may include the second emission layer EML-G, and the third light-emitting element ED-3 may include the third emission layer EML-B. The first emission layer EML-R may include a first quantum dot QD-C1. The second emission layer EML-G may include a second quantum dot QD-C2. The third emission layer EML-B may include a third quantum dot QD-C3.

The quantum dots QD-C1, QD-C2, and QD-C3 respectively included in the emission layers EML-R, EML-G, and EML-B may be stacked to form a layer. FIG. 7A illustrates that the quantum dots QD-C1, QD-C2, and QD-C3 having a cross-section in a circular shape are arranged to approximately form two layers, but aspects of the present disclosure are not limited thereto. For example, the arrangements of the quantum dots QD-C1, QD-C2, and QD-C3 may vary in accordance with thicknesses of the emission layers EML-R, EML-G, and EML-B, shapes of the quantum dots QD-C1, QD-C2, and QD-C3 included in the emission layers EML-R, EML-G, and EML-B, an average diameter of the quantum dots QD-C1, QD-C2, and QD-C3, etc. Specifically, in the emission layers EML-R, EML-G, and EML-B, the quantum dots QD-C1, QD-C2, and QD-C3 may be arranged to be adjacent to each other to form one layer, or may be arranged to form a plurality of layers such as two layers, and three layers.

The first quantum dot QD-C1 of the first light-emitting element ED-1 may emit red light. The second quantum dot QD-C2 of the second light-emitting element ED-2 may emit green light. The third quantum dot QD-C3 of the third light-emitting element ED-3 may emit blue light. For example, each of the quantum dots QD-C1, QD-C2, and QD-C3 may include a core and a shell covering the core. Each core of the quantum dots QD-C1, QD-C2, and QD-C3 may include a different material from each other. In addition, any two core among the cores of the quantum dots QD-C1, QD-C2, and QD-C3 may include the same material, and the remaining one core may include a different material.

In FIG. 7A, each of the quantum dots QD-C1, QD-C2, and QD-C3 is illustrated to have a similar diameter, but aspects of the present disclosure are not limited thereto. The quantum dots QD-C1, QD-C2, and QD-C3 may each have a different diameter. For example, the third quantum dot QD-C3 in the third light-emitting element ED-3, which emits light in a relatively short wavelength region, may have a relatively small average diameter compared to the first quantum dot QD-C1 in the first light-emitting element ED-1, and the second quantum dot QD-C2 in the second light-emitting element ED-2, which emit light in a relatively long wavelength region. The average diameter means an arithmetic average of particle diameters of a plurality of quantum dots. The particle diameter of the quantum dot may be an average value of the widths of the quantum dot particle on the cross-section thereof.

The electron transport regions ETR-1, ETR-2, and ETR-3 in the first to third light-emitting elements ED-1, ED-2, and ED-3 may be disposed in the opening OH, thereby capable of being divided. Unlike this, the electron transport regions ETR-1, ETR-2, and ETR-3 in the first to third light-emitting elements ED-1, ED-2, and ED-3 may be provided as a common layer. The electron transport regions ETR-1, ETR-2, and ETR-3 provided as a common layer may overlap the pixel regions PXA-R, PXA-G, and PXA-B, and the light-blocking region NPXA. The first light-emitting element ED-1 may include the first electron transport layer ETR-1, the second light-emitting element ED-2 may include the second electron transport layer ETR-2, and the third light-emitting element ED-3 may include the third electron transport layer ETR-3.

The first to third electron transport regions ETR-1, ETR-2, and ETR-3 may each have a single layer formed using a single material, a single layer formed using a plurality of different materials, or a multi-layered structure having a plurality of layers formed using a plurality of different materials. Each of the first to third electron transport regions ETR-1, ETR-2, and ETR-3 may have a thickness of, for example, about 1000 Å to about 1500 Å.

The first to third electron transport regions ETR-1, ETR-2, and ETR-3 may further include a known electron injection material and/or known electron transport materials. For example, the first to third electron transport regions ETR-1, ETR-2, and ETR-3 may include an anthracene-based compound. Alternatively, the first to third electron transport regions ETR-1, ETR-2, and ETR-3 may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate) (Bebq₂), 9,10-di(naphthalen-2-yl)anthracene (ADN), 1,3-bis[3,5-di(pyridin-3-yl)phenyl]benzene (BmPyPhB) and a mixture thereof. In addition, the first to third electron transport regions ETR-1, ETR-2, and ETR-3 may include 2,9-dimethyl-4,7-diphenyl-1,10-phenanthroline (BCP), diphenyl(4-(triphenylsilyl)phenyl)phosphine oxide (TSPO1), 4,7-diphenyl-1,10-phenanthroline (Bphen), etc.

The hole transport regions HTR-1, HTR-2, and HTR-3 may be disposed between the emission layers EML-R, EML-G, and EML-B, and the second electrode EL2. The hole transport regions HTR-1, HTR-2, and HTR-3 in the first to third light-emitting elements ED-1, ED-2, and ED-3 may be disposed in the opening OH, thereby capable of being divided. Unlike this, the hole transport regions HTR-1, HTR-2, and HTR-3 in the first to third light-emitting elements ED-1, ED-2, and ED-3 may be provided as a common layer. The hole transport regions HTR-1, HTR-2, and HTR-3 provided as a common layer may overlap the pixel regions PXA-R, PXA-G, and PXA-B, and the light-blocking region NPXA. The first light-emitting element ED-1 may include the first hole transport layer HTR-1, the second light-emitting element ED-2 may include the second hole transport layer HTR-2, and the third light-emitting element ED-3 may include the third hole transport layer HTR-3.

The first to third hole transport regions HTR-1, HTR-2, and HTR-3 may each have a single layer formed using a single material, a single layer formed using a plurality of different materials, or a multi-layered structure having a plurality of layers formed using a plurality of different materials. Each of the first to third hole transport regions HTR-1, HTR-2, and HTR-3 may have a thickness of, for example, about 50 Å to about 15,000 Å. Each of the first to third hole transport regions HTR-1, HTR-2, and HTR-3 may have a thickness of, for example, about 100 Å to about 10000 Å, for example about 100 Å to about 5000 Å.

The first to third hole transport regions HTR-1, HTR-2, and HTR-3 may include a known electron injection material and/or known electron transport material. For example, the first to third hole transport regions HTR-1, HTR-2, and HTR-3 may include a phthalocyanine compound such as copper phthalocyanine, N¹,N^{1′}-([1,1′-biphenyl]-4,4′-diyl)bis(N¹-phenyl-N⁴,N^{4′}-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N-(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonicacid (PANI/CSA), polyaniline/poly(4-styrenesulfonate) (PANI/PSS), N,N′-di(naphthalen-1-yl)-N,N′-diphenyl-benzidine (NPB), polyether ketone containing triphenylamine (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

In addition, the first to third hole transport regions HTR-1, HTR-2, and HTR-3 may include a carbazole-based derivative such as, N-phenyl carbazole, polyvinyl carbazole, a fluorene-based derivative, a triphenyl amine-based derivative such as N,N′-bis(3-methylphenyl)-N,N′-diphenyl-[1,1′-biphenyl]-4,4′-diamine (TPD), 4,4′,4″-tris(N-carbazolyl)triphenylamine (TCTA), N,N′-di(naphthalen-1-yl)-N,N′-diplienyl-benzidine (NPB), 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), 9-(4-tert-Butylphenyl)-3,6-bis(triphenylsilyl)-9H-carbazole (CzSi), 9-phenyl-9H-3,9′-bicarbazole (CCP), 1,3-bis(N-carbazolyl)benzene (mCP), 1,3-bis(1,8-dimethyl-9H-carbazol-9-yl)benzene (mDCP), etc.

The encapsulation layer TFE may include at least one inorganic layer (hereinafter, referred to as an encapsulation inorganic layer). In addition, the encapsulation layer TFE may include at least one organic layer (hereinafter, referred to as an encapsulation organic layer).

The encapsulation inorganic layer may protect the display element layer DP-EL from moisture/oxygen, and the encapsulation organic layer may protect the display element layer DP-EL from foreign substances such as dust particles. The encapsulation inorganic layer may include silicon nitride, silicon oxynitride, silicon oxide, titanium oxide, aluminum oxide, etc., but is not particularly limited thereto. The encapsulation organic layer may include an acrylate-based compound, an epoxy-based compound, etc. The encapsulation organic layer may include a photopolymerizable organic material but is not particularly limited thereto.

The optical layer PP may include a base substrate BL and a color filter layer CFL. The base substrate BL may be a member providing a base surface in which the color filter layer CFL is disposed. The base substrate BL may be a glass substrate, a metal substrate, a plastic substrate, etc. However, aspects of the present disclosure are not limited thereto, and the base substrate BL may be an inorganic layer, an organic layer, or a composite material layer.

The color filter layer CFL may include first to third filters CF-R, CF-G, and CF-B. The first to third filters CF-R, CF-G, and CF-B may respectively be disposed so as to correspond to the first to third light-emitting elements ED-1, ED-2, and ED-3. For example, the first filter CF-R may be a red filter, the second filter CF-G may be a green filter, and the third filter CF-B may be a blue filter. The first to third filters CF-R, CF-G, and CF-B may be disposed corresponding to the first to third pixel regions PXA-R, PXA-G, and PXA-B, respectively.

The first to third filters CF-R, CF-G, and CF-B may each include a polymer photosensitive resin and a pigment or dye. The first filter CF-R may include a red pigment, or red dye, the second filter CF-G may include a green pigment, or green dye, and the third filter CF-B may include a blue pigment, or blue dye. However, aspects of the present disclosure are not limited thereto, and the third filter CF-B may include no pigment or no dye. The third filter CF-B may include a polymer photosensitive resin, and include no pigment, or no dye. The third filter CF-B may be transparent. The third filter CF-B may be formed using a transparent photosensitive resin.

The color filter layer CFL may further include a buffer layer BFL. For example, the buffer layer BFL may be a protection layer that protects the first to third filters CF-R, CF-G, and CF-B. The buffer layer BFL may be disposed between the encapsulation layer TFE and the first to third filters CF-R, CF-G, and CF-B. The buffer layer BFL may be an inorganic layer including at least one inorganic material of silicon nitride, silicon oxide, or silicon oxynitride. The buffer layer BFL may include a single layer or multi layer.

In addition, the first filter CF-R and the second filter CF-G may each be a yellow filter. The first filter CF-R and the second filter CF-G may be provided as a single unit without being distinguished from each other.

Although not illustrated, the color filter layer CFL may further include a light-blocking part (not illustrated). The light-blocking part may be a black matrix. The light-blocking part may be formed by including organic light-blocking materials or inorganic light-blocking materials containing a black pigment or black dye. The light-blocking part may prevent a light leakage phenomenon and may separate boundaries between the adjacent filters CF-R, CF-G, and CF-B.

FIG. 7B is a cross-sectional view illustrating a display module according to another aspect of the present disclosure. In descriptions on FIG. 7B, the duplicated content as the descriptions explained with reference to FIG. 1 to FIG. 7A will not be explained again, and differences will be mainly described.

As compared to the display module DM illustrated FIG. 7A, a display module DM-1 illustrated in FIG. 7B differs from arranged locations of the electron transport regions ETR-1, ETR-2, and ETR-3 and hole transport regions HTR-1, HTR-2, and HTR-3. Referring to FIG. 7B, each of the light-emitting elements ED-1, ED-2, and ED-3 may include a first electrode EL1, hole transport regions HTR-1, HTR-2, and HTR-3 disposed on the first electrode EL1, emission layers EML-R, EML-G, and EML-B disposed one the hole transport regions HTR-1, HTR-2, and HTR-3, electron transport regions ETR-1, ETR-2, and ETR-3 disposed on the emission layers EML-R, EML-G, and EML-B, and a second electrode EL2 disposed on the electron transport regions ETR-1, ETR-2, and ETR-3. The electron transport regions ETR-1, ETR-2, and ETR-3 may be disposed between the emission layers ML-R, EML-G, and EML-B and the second electrode EL2, and the hole transport regions HTR-1, HTR-2, and HTR-3 may be disposed between the first electrode EL1 and the emission layers EML-R, EML-G, and EML-B.

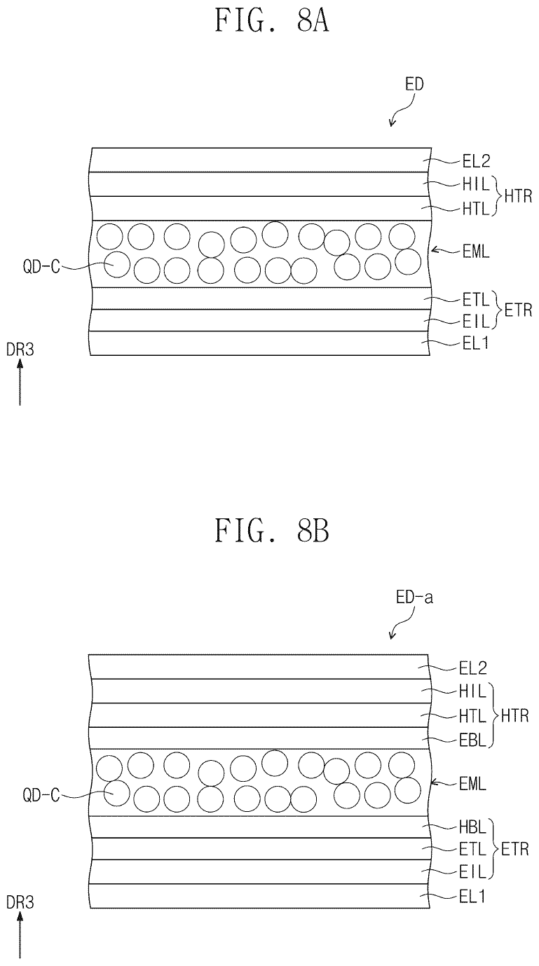

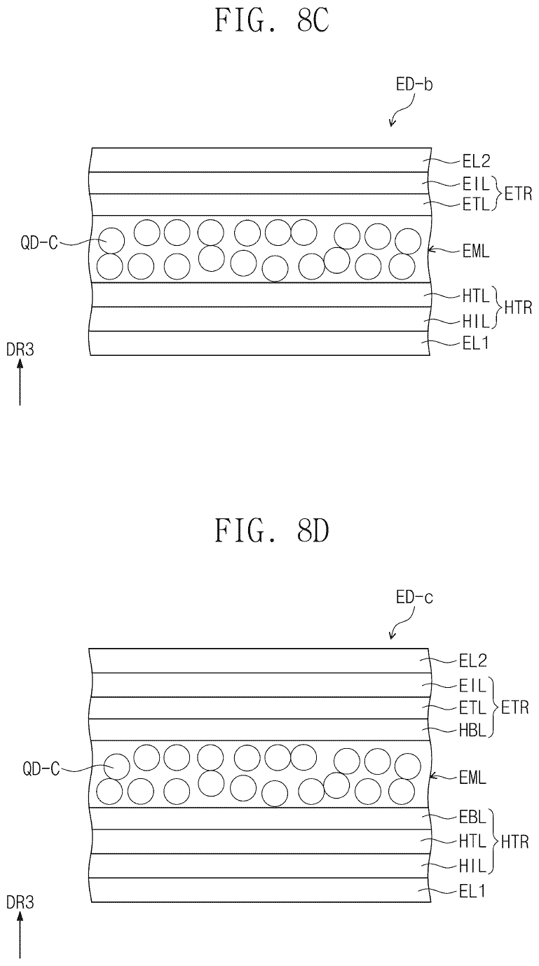

FIG. 8A to FIG. 8D are cross-sectional views illustrating light-emitting elements ED, ED-a, ED-b, ED-c according to an aspect. Referring to FIG. 8A to FIG. 8D, the light-emitting elements ED, ED-a, ED-b, and ED-c may include a first electrode EL1, an emission layer EML disposed on the first electrode EL1, a second electrode EL2 disposed on the emission layer EML, a hole transport region HTR disposed between the first electrode EL1 and the second electrode EL2, and an electron transport region disposed between the first electrode EL1 and the second electrode EL2. The emission layer EML may be disposed between the electron transport region ETR and the hole transport region HTR. The emission layer EML may include a quantum dot QD-C according to an aspect. The quantum dot QD-C according to an aspect will be described later in more detail.

At least one among light-emitting elements ED and ED-a, which will be described with reference to FIG. 8A and FIG. 8B, may be similarly applied to at least one among the first to third light-emitting elements ED-1, ED-2, and ED-3 illustrated in FIG. 7B. At least one among light-emitting elements ED-b and ED-c, which will be described with reference to FIG. 8C and FIG. 8D may be similarly applied to at least one among the first to third light-emitting elements ED-1, ED-2, and ED-3 illustrated in FIG. 7B.

Referring to FIG. 8A and FIG. 8B, the light-emitting elements ED, and ED-a may include a first electrode EL1, an electron transport region ETR, an emission layer EML, a hole transport region HTR, and a second electrode EL2, which are sequentially stacked. The electron transport region ETR may include an electron injection layer EIL, and an electron transport layer ETL disposed on the electron injection layer EIL. The hole transport region HTR may include a hole transport layer HTL, and a hole injection layer HIL disposed on the hole transport layer HTL.

In the light-emitting element ED-a illustrated in FIG. 8B, the electron transport region ETR may further include a hole blocking layer HBL disposed on the electron transport layer ETL. The hole transport region HTR may further include an electron blocking layer EBL disposed between the emission layer EML and the hole transport layer HTL.

Referring to FIG. 8C and FIG. 8D, the light-emitting elements ED-b, and ED-c may include a first electrode EL1, a hole transport region HTR, an emission layer EML, an electron transport region ETR, and a second electrode EL2, which are sequentially stacked. The electron transport region ETR may include an electron transport layer ETL, and an electron injection layer EIL disposed on the electron transport layer ETL. The hole transport region HTR may include a hole injection layer HIL, and a hole transport layer HTL disposed on the hole injection layer HIL.

In the light-emitting element ED-c illustrated in FIG. 8D, the hole transport region HTR may further include an electron blocking layer EBL disposed on the hole transport layer HTL. The electron transport region ETR may further include a hole blocking layer HBL, disposed between the emission layer EML and the electron transport layer ETL.

Unlike what is illustrated in FIG. 8A to FIG. 8D, any one among the electron injection layer EIL, and the electron transport layer ETL may be omitted. Any one among the hole injection layer HIL and the hole transport layer HTL may be omitted.

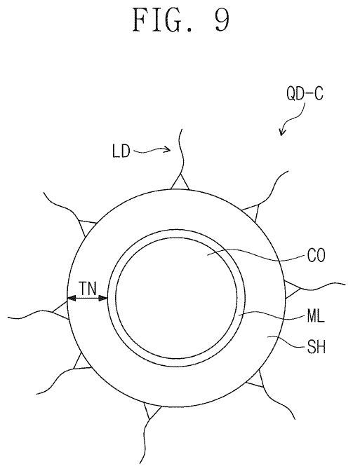

FIG. 9 is a view schematically illustrating a quantum dot according to an aspect. The description for the quantum dot QD-C according to an aspect may be similarly applied to at least one among the above-described first to third quantum dots QD-C1, QD-C2, and QD-C3. For example, at least one among the first and second quantum dots QD-C1 and QD-C2 may be the quantum dot QD-C according to an aspect. As used herein, the quantum dot QD-C may refer to a crystal of a semiconductor compound.

In an aspect, the quantum dot QD-C may include a core CO, an intermediate layer ML, and a shell SH. The intermediate layer ML may cover the core CO, and the shell may cover the intermediate layer ML. The quantum dot QD-C may further include a ligand LD.

The ligand LD may resolve defects in the core CO and/or the shell SH, and increase stability of the quantum dot QD-C. Eight ligands LD are shown in FIG. 9, but this is for illustrative purposes, and the number of ligands LD is not limited thereto.

For example, the ligand LD may include an organic ligand and/or a metal halide. The ligand LD may include at least one of octadecane, octadecene, methanethiol, ethanethiol, propanethiol, butanethiol, pentanethiol, hexanethiol, octanethiol, dodecanethiol, hexadecanethiol, octadecanethiol, benzyl thiol, methylamine, ethylamine, propylamine, butylamine, pentylamine, hexylamine, octylamine, dodecylamine, hexadecylamine, octadecylamine, dimethylamine, diethylamine, dipropylamine, oleylamine, trioctylamine, methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid, trimethyl phosphine, methyldiphenyl phosphine, triethyl phosphine, ethyldiphenyl phosphine, trioctyl phosphine, trimethyl phosphine oxide, methyldiphenyl phosphine oxide, triethyl phosphine oxide, ethyldiphenyl phosphine oxide, or trioctyl phosphine oxide. However, these are suggested as examples, and a known ligand material to the related art may be included without limitation as the ligand LD.

In an aspect, the core CO may include a multi-component-based compound including copper (CU), indium (In), gallium (Ga), and sulfur(S). Hereinafter, the “multi-component-based compound including copper (CU), indium (In), gallium (Ga), and sulfur(S)” is referred to as a “CIGS compound”.

The core CO including the CIGS compound may have an absorption wavelength of about 350 nm to about 580 nm. The core CO including the CIGS compound may exhibit a high absorption rate for light with a wavelength of about 350 nm to about 580 nm. The core CO may absorb blue light with a wavelength of about 350 nm to about 580 nm, thereby capable of emitting green light or red light. By controlling the size of the core CO, and a thickness of the shell SH, a wavelength of light emitted in the quantum dot QD-C may vary.

The shell SH effectively passivates defects present in a surface of the core CO, which may increase luminous efficiency and stability of the quantum dot QD-C. The shell SH according to an aspect may include ZnS. A thickness TN of the shell SH may be about 0.1 nm to about 2 nm. The quantum dot QD-C including the shell SH that contains ZnS may exhibit high material stability for ultraviolet ray. The shell SH contains ZnS having a larger band gap than a band gap of the core CO, and thus may contribute to improvements in efficiency and stability of the quantum dot QD-C.

In an aspect, the intermediate layer ML may contain zinc (Zn). The intermediate layer ML may further contain S. In the method for manufacturing a light-emitting element, according to an aspect, to be described later, the intermediate layer ML may be formed by an in-situ process. During the forming of the core CO, forming an intermediate layer ML may be performed before cooling and purifying.

The intermediate layer ML formed through the in-situ process is a single layer, and a thickness of the intermediate layer ML may be very thin. The intermediate layer ML having the very thin thickness is difficult to measure the thickness, and may have a continuous composition with the core CO. When the core CO covered with the intermediate layer ML formed by providing Zn via the in-situ process is subjected to a surface analysis by X-ray photoelectron spectroscopy (XPS), Cu, In, Ga, S and Zn may be all detected. Since the intermediate layer ML is very thin, all Cu, In, Ga, S, and Zn may be detected on the surface analysis of XPS. If Cu, In, and Ga are not detected, but only S and Zn are detected through the surface analysis, there may be an intermediate layer formed by a process other than the in-situ process.

In the quantum dot QD-C according to an aspect, Zn is provided between the core CO including a CIGS compound and the shell SH including ZnS, and thus the intermediate layer ML formed through the in-situ process may be included. Therefore, the quantum dot QD-C according to an aspect may have a full width at half maximum of less than about 50 nm, and a quantum yield of about 80% or more. For example, the quantum dot QD-C according to an aspect may have the full width at half maximum of about 49 nm or less, and the quantum yield of about 88% or more. The quantum dot QD-C having the full width at half maximum of less than about 50 nm, and the quantum yield of about 80% or more may emit light having improved color purity and may exhibit excellent luminous efficiency.

The conventional quantum dot including the CIGS compound has a large full width at half maximum (FWHM) (for example, the full width at half maximum is greater than about 50 nm) and exhibit low color purity. The conventional quantum dot having low color purity is not suitable for a quantum dot of a display module providing an image. When the shell including ZnS is formed without an intermediate layer to the core including the CIGS compound, the full width at half maximum significantly increases after forming the shell. As compared to the full width at half maximum in the core state, the full width at half maximum in a state after the shell covering the core is formed exhibits a significantly increased value. In addition, the conventional quantum dot in which the shell including ZnS is formed, without an intermediate layer, to the core including the CIGS compound exhibits low material stability for ultraviolet ray.

Unlike this, the quantum dot QD-C according to an aspect includes the intermediate layer ML formed via the in-situ process by providing Zn between the core including the CIGS compound and the shell including ZnS and thus may exhibit a reduced full width at half maximum. Therefore, the light-emitting elements ED, ED-a, ED-b, and ED-c (FIG. 8A to FIG. 8D) including the quantum dot QD-C according to an aspect may emit light having improved color purity, and may exhibit high-efficiency characteristics. The electronic apparatus EA (FIG. 1) including the light-emitting elements ED, ED-a, ED-b, and ED-c, according to an embodiment may exhibit excellent display quality.

The shell SH in the quantum dot QD-C according to an aspect may serve as a protection layer for preventing the core from chemical alteration to maintain semiconductor properties and/or a charging layer for imparting the quantum dot with electrophoretic properties. The shell SH may have a single layer, or multilayer. The quantum dot QD-C may have a concentration gradient in which the concentration of an element present in the shell SH is decreased toward the core CO.

The shell SH may further include a metal or non-metal oxide, a semiconductor compound, or a combination thereof. Examples of the metal or non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a ternary compound such as MgAl₂O₄, CoFe₂O₄, NiFe₂O₄, or CoMn₂O₄; or an arbitrary combination thereof. Examples of the semiconductor compound may include: as described in the present specification, a III-VI group semiconductor compound; a II-VI group semiconductor compound; a III-V group semiconductor compound; a III-VI group semiconductor compound; a I-III-VI group semiconductor compound; a IV-VI group semiconductor compound; or an arbitrary combination thereof. For example, the semiconductor compound may include ZnSe, ZnTe, ZnSeS, ZnTeS, ZnGaS, GaAs, GaP, GaS, GaSe, AgGaS, AgGaS₂, GaSb, HgS, HgSe, HgTe, InAs, InP, InGaP, InSb, AlAs, AlP, AlSb, or an arbitrary combination thereof.

Each element included in the multi-component compound such as the binary compound, or the ternary compound may be present at uniform concentration or non-uniform concentration within a particle. That is, Formula above means types of elements included in the compound, and an element ratio in the compound may vary.

The following descriptions will be applied to one or two quantum dots other than the quantum dot QD-C according to an aspect, among the first to third quantum dots QD-C1, QD-C2, and QD-C3. Hereinafter, for convenience of the descriptions, the one or two quantum dots are referred to as a ‘sub quantum dot’.

Depending on the crystal size of the sub quantum dot, light with various emission wavelengths may be emitted. The sub quantum dot may have a diameter of, for example, about 1 nm to about 10 nm.

The sub quantum dot may be synthesized by a wet chemical process, an organic metal chemical vapor deposition process, a molecular beam epitaxy process, similar processes, or the like. The wet chemical process may be a method of mixing an organic solvent and a precursor material, and then growing a quantum dot particle crystal. When the crystal is grown, the organic solvent may naturally serve as a dispersant that is coordinated to the surface of a quantum dot crystal and may adjust the growth of the crystal. Therefore, the wet chemical process may control the growth of the quantum dot particles through a simpler and more cost-effective process than a vapor deposition method such as metal organic chemical vapor deposition (MOCVD) or molecular beam epitaxy (MBE).

The sub quantum dot may include a II-VI group semiconductor compound, a I-II-VI group semiconductor compound, a II-IV-VI group compound, a I-II-IV-VI group semiconductor compound, a III-V group semiconductor compound, a III-VI group semiconductor compound, a I-III-VI group semiconductor compound, a IV-VI group semiconductor compound, a II-IV-V group semiconductor compound, a IV group element or compound, or any combination thereof. As used herein, the term “Group” refers to a group of the IUPAC periodic table.

Examples of the II-VI group semiconductor compound may include: binary compounds such as ZnS, ZnSe, ZnTe, ZnO, HgS, HgSe, HgTe, MgSe, or MgS; ternary compounds such as ZnSeS, ZnSeTe, ZnSTe, HgSeS, HgSeTe, HgSTe, HgZnS, HgZnSe, HgZnTe, MgZnSe, or MgZnS; quaternary compounds such as HgZnSeS, HgZnSeTe, or HgZnSTe; or any combination thereof.

The II-VI group semiconductor compound may further include a I metal group and/or a IV group element. The I-II-VI group compound may be selected from CuSnS or CuZnS, and as the II-IV-VI group compound, ZnSnS and the like may be selected. The I-II-IV-VI group compound may be selected from quaternary compounds selected from the group consisting of Cu₂ZnSnS₂, Cu₂ZnSnS₄, Cu₂ZnSnSe₄, Ag₂ZnSnS₂ or a mixture thereof.

Examples of the III-V group semiconductor compound may include binary compounds such as GaN, GaP, GaAs, GaSb, AlN, AlP, AlAs, AlSb, InN, InP, InAs, or InSb; ternary compounds such as GaNP, GaNAs, GaNSb, GaPAs, GaPSb, AlNP, AlNAs, AlNSb, AlPAs, AlPSb, InGaP, InNP, InAlP, InNAs, InNSb, InPAs, or InPSb; quaternary compounds such as GaAlNP, GaAlNAs, GaAlNSb, GaAlPAs, GaAlPSb, GaInNP, GaInNAs, GalnNSb, GalnPAs, GalnPSb, InAlNP, InAlNAs, InAlNSb, InAlPAs, or InAlPSb; or any combination thereof. The III-V group semiconductor compound may further include a II group element. Examples of the III-V group semiconductor compound further including the II group element may include InZnP, InGaZnP, InAlZnP, etc.

Examples of the III-VI group semiconductor compound may include binary compounds such as GaS, Ga₂S₃, GaSe, Ga₂Se₃, GaTe, InS, InSe, In₂Se₃, or InTe; ternary compounds such as InGaS₃, or InGaSe₃; or any combination thereof.

Examples of the I-III-VI group semiconductor compound may include ternary compounds such as AgInS, AgInS₂, AgInSe₂, AgGaS, AgGaS₂, AgGaSe₂, CuInS, CulnS₂, CuInSe₂, CuGaS₂, CuGaSe₂, CuGaO₂, AgGaO₂, or AgAlO₂; quaternary compounds such as AgInGaS₂, or AgInGaSe₂; or any combination thereof.

Examples of the IV-VI group semiconductor compound may include binary compounds such as SnS, SnSe, SnTe, PbS, PbSe, or PbTe; ternary compounds such as SnSeS, SnSeTe, SnSTe, PbSeS, PbSeTe, PbSTe, SnPbS, SnPbSe, or SnPbTe; quaternary compounds such as SnPbSSe, SnPbSeTe, or SnPbSTe; or any combination thereof.

Examples of the II-IV-V group semiconductor compound may include a ternary compound selected from the group consisting of ZnSnP, ZnSnP₂, ZnSnAs₂, ZnGeP₂, ZnGeAs₂ or a mixture thereof.

The IV group element or compound may include monoatomic compounds such as Si, or Ge; binary compounds such as SiC, or SiGe; or any combination thereof.

Each element contained in the multi-component compounds such as the binary compound, the ternary compound, or the quaternary compound may be present in particles at a uniform concentration or a non-uniform concentration. That is, the formula above may refer to types of the elements contained in the compound, and an element ratio in the compound may be different. For example, AgInGaS₂ may refer to AgInₓGa₁₋ₓS₂ (where x is a real number between 0 to 1).

The sub quantum dot may have a single structure in which a concentration of each element contained in the corresponding quantum dot is uniform, or a core-shell dual structure. For example, a material contained in the core may be different from a material contained in the shell.

The shell of the sub quantum dot may serve as a protection layer for preventing the core from chemical alteration to maintain semiconductor properties and/or a charging layer for imparting electrophoretic properties to the quantum dot. The shell may have a single layer or a multilayer. The core/shell structure may have a concentration gradient that the concentration of the elements present in the shell may decrease gradually getting toward the core.

Examples of the shell of the sub quantum dot may include an oxide of a metal or non-metal, a semiconductor compound, a combination thereof, etc. The content described with reference to the shell SH may be similarly applied to examples of the metal or non-metal oxide, the semiconductor compound, or a combination thereof.

The sub quantum dot may have a full width at half maximum (FWHM) of an emission wavelength spectrum of about 45 nm or less, specifically about 40 nm or less, and more specifically about 30 nm or less, and when FWHM falls within this range, color purity or color reproducibility may be improved. In addition, light emitted through the sub quantum dot may be emitted in all directions, and thus an optical viewing angle may be improved. In addition, the sub quantum dot may be, specifically, in the form of spherical, pyramidal, multi-arm, or cubic nanoparticles, nanotubes, nanowires, nanofibers, nanoplatelets, etc.

An energy band gap may be adjusted by controlling the size of the sub quantum dot or controlling the element ratio in the compound constituting the sub quantum dot, and thus light with various wavelengths may be emitted in the emission layer EML including the sub quantum dot. Therefore, by using the sub quantum dot as previously described (quantum dots having different sizes or having different element ratios in the quantum dot compound), the light-emitting elements ED, and ED-a, ED-b, and ED-c (FIGS. 8A to 8D) emitting light with various wavelengths may be implemented. Specifically, the sizes of the sub quantum dot and the element ratios constituting the sub quantum dot in the compound may be selected such that red, green, and/or blue light is emitted. In addition, the sub quantum dots may be configured to emit white light by combining various colors of light.

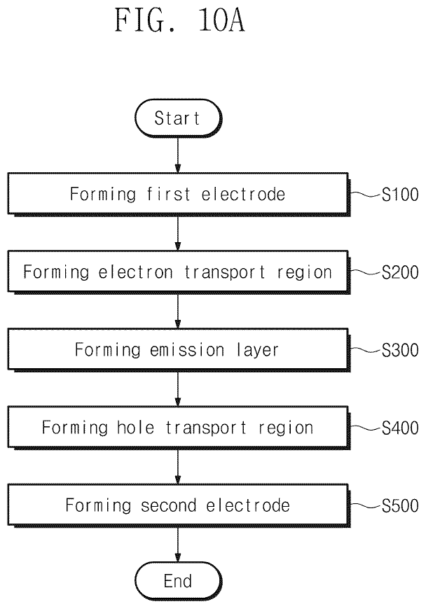

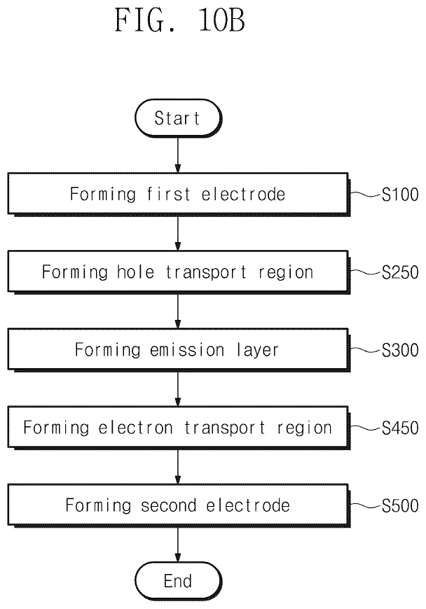

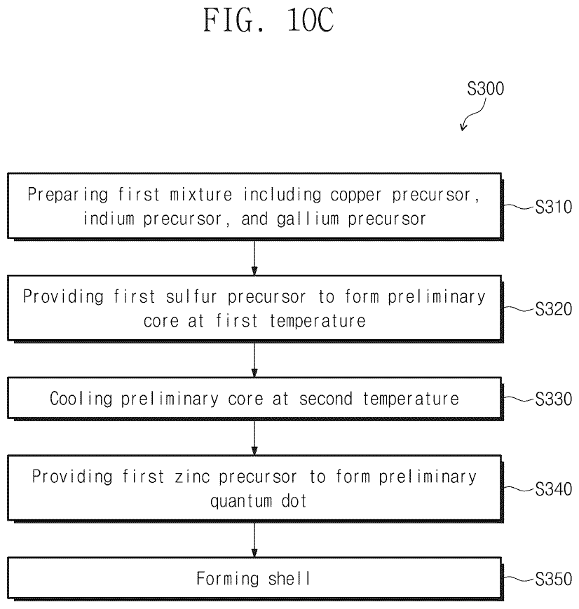

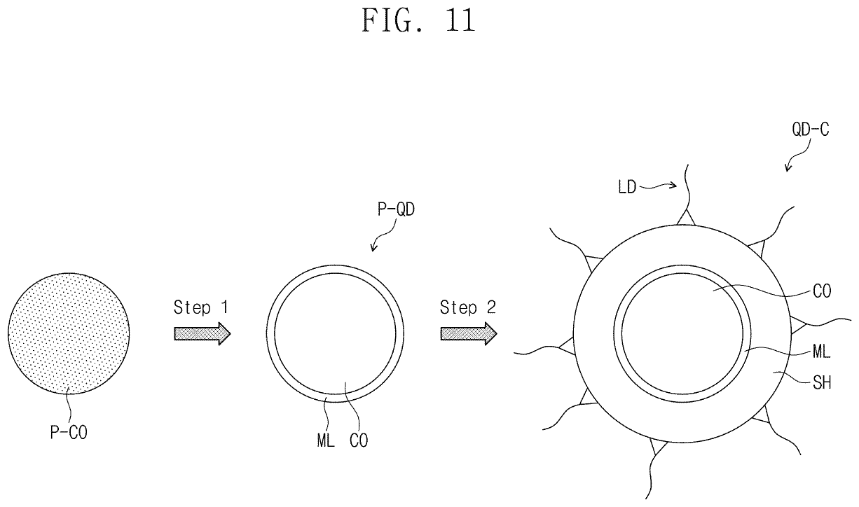

The light-emitting element according to an embodiment may be manufactured by the method for manufacturing a light-emitting element, according to an embodiment. FIG. 10A to FIG. 10 C are each a flow chart showing the method for manufacturing a light-emitting element, according to an embodiment. FIG. 11 is a diagram schematically showing steps of manufacturing a light-emitting element, according to an aspect. Hereinafter, for descriptions for FIG. 10A to FIG. 11, the duplicated content as the descriptions explained with reference to FIG. 1 to FIG. 9 will not be explained again, and differences will be mainly described.

Referring to FIG. 10A and FIG. 10B, the method for a light-emitting element according to an aspect may include: forming a first electrode S100; forming an emission layer on the first electrode S300; forming a second electrode on the emission layer S500; forming a hole transport region S400 and S250; and forming an electron transport region S200 and S450.

Any one among the forming of an electron transport region S200 and S450 and the forming of a hole transport region S400 and S250 may be performed between the forming of a first electrode S100 and the forming of an emission layer S300, and the other one may be performed between the forming of an emission layer S300 and the forming of a second electrode S500. FIG. 10A illustrates that the forming of an electron transport region S200 is performed between the forming of the first electrode S100 and the forming of the emission layer S300 and the forming of a hole transport region S400 is performed between the forming of an emission layer and the forming of a second electrode S500. Unlike this, FIG. 10B illustrates that the forming of a hole transport region S250 is performed between the forming of a first electrode S100 and the forming of an emission layer S300 and the forming of an electron transport region S450 is performed between the forming of an emission layer and the forming of a second electrode S500.

The first electrode EL1 (FIG. 8A to FIG. 8D), the second electrode EL2 (FIG. 8A to FIG. 8D), the electron transport region ETR (FIG. 8A to FIG. 8D), and the hole transport region HTR (FIG. 8A to FIG. 8D) may be formed by providing the above-described materials. The emission layer EML (FIG. 8A to FIG. 8D) may be formed by providing the quantum dot QD-C (FIG. 11). The quantum dot QD-C (FIG. 11) may be formed using the method for manufacturing a quantum dot according to an aspect. The forming of the emission layer S300 may include the method for manufacturing a quantum dot, according to an aspect.

FIG. 10C may be a flow chart showing a method for manufacturing a quantum dot. Referring to FIG. 10C, the method for manufacturing a quantum dot may include: preparing a first mixture S310; forming a preliminary core at a first temperature S320; cooling the preliminary core at a second temperature S330; forming a preliminary quantum dot S340; and forming a shell S350.

As used herein, a metal precursor is a material including metal and a component chemically bonded to metal, wherein the chemically bonded component may refer to a component that easily dissociates with metal. For example, the metal precursor may be provided as a type of salt. The metal of the metal precursor may be a component included in the quantum dot QD-C according to an aspect. The metal may be copper, indium, gallium, sulfur, zinc, etc.

The copper precursor, the indium precursor, the gallium precursor, and the first sulfur precursor may each include metal powder, a metal halide, a metal sulphate, a metal acetylacetonate, a metal hydroxide, a metal oxide, a metal nitrate, a metal carboxylate, an alkylated metal compound, or a combination thereof.

For example, the copper precursor may include at least one among copper halide, copper acetate, or copper nitrate. The copper halide may include at least one among Cl, Br, or I, as a halogen material. However, this is suggested as an example, and aspects of the present disclosure are not limited thereto.

The gallium precursor may include at least one among gallium nitrate, gallium phosphide, gallium (III) chloride, gallium (III) acetylacetonate, gallium (III) bromide, gallium (III) chloride, gallium (III) fluoride, gallium (III) iodide, gallium (III) nitrate hydrate, gallium (III) sulfate, or gallium (III) sulfate hydrate. However, this is suggested as an example, and aspects of the present disclosure are not limited thereto.

The indium precursor may include at least one among indium (III) acetylacetonate, indium (III) bromide, indium (III) chloride, indium (III) fluoride, indium (III) iodide, indium (III) acetate, trimethyl indium, alkyl indium, aryl indium, indium (III) myristate, indium (III) myristate acetate, or indium (III) di-myristate acetate. However, this is suggested as an example, and aspects of the present disclosure are not limited thereto. The aryl is an aryl group and refers to an arbitrary functional group or substituent derived from an aromatic hydrocarbon ring. The aryl group may be a monocyclic aryl group, or polycyclic aryl group. The ring-forming carbon number of the aryl group may be 6 to 60, 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzo[fluoranthenyl] group, a chrysene group, etc., but are not limited thereto.

The first sulfur precursor may include at least one of S-oleylamine, 1-dodecanethiol, trioctylphosphine-sulfur (TOP-S), S-tributylphosphine (S-TBP), S-triphenylphosphine (S-TPP), S-trioctylamine (S-TOA), S-octadecene (S-ODE), S-diphenylphosphine (S-DPP), S-dodecylamine, octanethiol, octadecanethiol, α-toluenethiol, allyl mercaptan, or bis(trimethylsilyl) sulfide. For example, the sulfur precursor may include sulfur-oleylamine (S-oleylamine) and 1-dodecanethiol.

The first mixture may include a copper precursor, an indium precursor, and a gallium precursor. The first mixture may further include at least one of oleylamine, 1-octadecene, octadecane, methanethiol, ethanethiol, propanethiol, butanethiol, pentanethiol, hexanethiol, octanethiol, hexadecanethiol, benzylthiol, methane amine, ethane amine, propane amine, butylamine, pentylamine, hexylamine, octylamine, dodecylamine, hexadecylamine, octadecylamine, dimethylamine, diethylamine, dipropylamine, trioctylamine, methanoic acid, ethanoic acid, propanoic acid, buthanoic acid, pentanoic acid, hexanoic acid, heptanoic acid, octanoic acid, dodecanoic acid, hexadecanoic acid, octadecanoic acid, oleic acid, benzoic acid, trimethyl phosphine, methyldiphenyl phosphine, triethyl phosphine, ethyldiphenyl phosphine, trioctyl phosphine, trimethyl phosphine oxide, methyldiphenyl phosphine oxide, triethyl phosphine oxide, ethyldiphenyl phosphine oxide, or trioctyl phosphine oxide. At least one among suggested from oleylamine to trioctyl phosphine oxide may be provided as a precursor material for forming a ligand. For example, the first mixture may include a copper precursor, an indium precursor, a gallium precursor, oleylamine, and 1-octadecene.

The manufacturing of the first mixture by mixing a copper precursor, an indium precursor, a gallium precursor, oleylamine, and 1-octadecene may be performed at about 120° C. The first mixture may be treated under vacuum for about 30 minutes and then transferred to a N₂ atmosphere. However, this is exemplary, and the temperature and the method for manufacturing the first mixture are not limited.

Subsequently, a first sulfur precursor may be provided to the first mixture, and the mixture may be heated to a first temperature, thereby capable of forming a preliminary core P-CO (FIG. 11). The copper precursor, the indium precursor, the gallium precursor, and the first sulfur precursor may be chemically reacted, and thus the preliminary core P-CO (FIG. 11) may be formed. The preliminary core P-CO (FIG. 11) may include a CIGS compound.

The first temperature may be about 230° C. to about 330° C. The forming of the preliminary core P-CO (FIG. 11) may be performed at the first temperature of about 230° C. to about 330° C. for about 10 minutes to about 30 minutes. For example, the forming of the preliminary core P-CO (FIG. 11) may be performed at the first temperature of about 300° C. for about 20 minutes.

In FIG. 11, ‘Step 1’ shows the cooling of the preliminary core P-CO, and the providing the first zinc precursor to the preliminary core P-CO. A preliminary quantum dot P-QD may be formed by providing the first zinc precursor to the preliminary core P-CO. The preliminary quantum dot P-QD may include a core CO, and an intermediate layer ML.

The cooling of the preliminary core P-CO may be performed at a second temperature. The second temperature may be lower than the first temperature. The second temperature may be about 20° C. to about 280° C. For example, the second temperature may be about 140° C. to about 280° C. For example, the second temperature may be about 140° C. The cooling and purification may not be performed prior to the cooling of the preliminary core P-CO.

The first zinc precursor may include at least one among dimethyl zinc, diethyl zinc, zinc acetate, zinc acetylacetonate, zinc iodide, zinc bromide, zinc chloride, zinc fluoride, zinc oleate, zinc carbonate, zinc cyanide, zinc nitrate, zinc oxide, zinc peroxide, zinc perchlorate, zinc sulfate, or zinc carboxylate. For example, the first zinc precursor may include at least one among ZnCl₂ and Zn(OA)₂. The first zinc precursor may be dissolved in a solvent such as tri-n-octylphosphine and provided.

The intermediate layer ML may be formed from the first zinc precursor provided to the preliminary core P-CO. The intermediate layer ML according to an aspect may be formed by an in-situ process by providing the first zinc precursor. The in-situ process may be performed at the second temperature. The second temperature may be about 20° C. to about 280° C. The second temperature may include room temperature. When the number of moles of the provided first zinc precursor is the same, the quantum dot QD-C including the intermediate layer ML formed at a relatively low temperature among the above-described second temperature ranges may exhibit a narrow full width at half maximum.

When the second temperature is below about 20° C., the first zinc precursor is not sufficiently activated, and thus no intermediate layer may be formed. When the second temperature is higher than about 280° C., the first zinc precursor may not be mildly treated, and a surface of the preliminary core is damaged. Unlike this, when the in-situ process is performed at the second temperature of about 20° C. to about 280° C., the intermediate layer ML may be easily formed, and the quantum dot QD-C including the intermediate layer ML may exhibit excellent material stability. The method for manufacturing a light-emitting element, according to an aspect, including the performing of the in-situ process at the second temperature may exhibit excellent processibility.

During the performing of the in-situ process, a core CO may be formed from the preliminary core P-CO. During the performing of the in-situ process, the core CO may be substantially formed. It may be in the preliminary core P-CO state prior to the in-situ process. For example, the in-situ process may be performed at about 140° C. for about 20 minutes. However, this is for illustrative purposes, and an execution period of the in-situ process may be adjusted to facilitate the formation of the desired intermediate layer ML.

When the second temperature is about 260° C. to about 280° C., the number of moles of the first zinc precursor provided is about 0.01 times to about 4 times the number of moles of the gallium precursor. In addition, the number of moles of the first zinc precursor provided may be about 0.1 times to about 4 times the number of moles of the gallium precursor. As described above, the gallium precursor may be included in the first mixture. When the second temperature is higher than about 200° C. and lower than about 260° C., the number of moles of the first zinc precursor provided may be more than about 4 times and about 36.90 times or less the number of moles of the gallium precursor. When the second temperature is about 20° C. to about 200° C., the number of moles of the first zinc precursor provided may be about 0.1 times to about 73.90 times the number of moles of the gallium precursor. In addition, when the second temperature is about 20° C. to about 200° C., the number of moles of the first zinc precursor provided may be about 0.1 times to about 73.90 times the number of moles of the gallium precursor. Since the number of moles of the first zinc precursor according to the second temperature falls within the above-described range, the desired intermediate layer ML may be easily formed.

When the second temperature is the same, depending on the number of moles of the first zinc precursor provided, the full width at half maximum and/or quantum efficiency of the quantum dot QD-C may vary. When the second temperature is the same, if a relatively small amount of the first zinc precursor is provided, a quantum dot QD-C exhibiting a narrow full width at half maximum (for example, less than about 50 nm) and/or improved quantum efficiency (for example, about 80% or more) may be formed. Therefore, the quantum dot QD-C including the intermediate layer ML may exhibit improved color purity and excellent luminous efficiency.

The intermediate layer ML formed via the in-situ process may have a very thin thickness. The intermediate layer ML may include Zn derived from the first zinc precursor. In addition, the intermediate layer ML may further include S derived from the first sulfur precursor provided during the synthesis of the preliminary core P-CO.

The conventional quantum dot includes cooling and purification during synthesis of the core. In the method for manufacturing a light-emitting element, according to an aspect, the cooling and purification of the preliminary core P-CO may not be performed prior to the providing of the first zinc precursor. That is, the cooling and purification may not be performed prior to the in situ-process. The cooling and purification may be performed at a temperature of about 20° C. to about 30° C. In the method for manufacturing a light-emitting element, according to an aspect, the cooling and purification may be performed after the forming of the preliminary quantum dot P-QD including the core CO and the intermediate layer ML by the providing of the first zinc precursor.

After the forming of the preliminary quantum dot P-QD, forming a shell SH may be performed. In FIG. 11, the ‘Step 2’ may exhibit a step of preparing and providing a material for forming the shell SH to the preliminary quantum dot P-QD.

The solvent may be prepared prior to the forming of the shell SH. For example, tri-n-octylamine may be provided in a flask as a solvent. Thereafter, the solvent may be treated in a vacuum for about 30 minutes and maintained under a N₂ atmosphere.

The preliminary quantum dot P-QD, a second zinc precursor, and a second sulfur precursor may be provided in the prepared solvent to form a second mixture. The second mixture may further include hydrofluoric acid (HF). The hydrofluoric acid may be provided for increasing stability of the forming of the shell SH. The hydrofluoric acid may be dissolved in water and provided. The second zinc precursor may include the same or different material as the first zinc precursor. As an example material of the second zinc precursor, the above-exemplified material as the first zinc precursor may be included. The second sulfur precursor may include the same or different material as the first sulfur precursor. As an example material of the second sulfur precursor, the above-exemplified material as the first sulfur precursor may be included. For example, the second zinc precursor may include zinc oleate. The second sulfur precursor may include TOP-S.

Next, in order to remove an unnecessary solvent from the second mixture, a vacuum pump may be used. After removing the unnecessary solvent, the second mixture may be maintained under a N₂ atmosphere. Thereafter, the shell SH may be formed by heating the mixture to a third temperature. For example, the third temperature may be about 280° C., and may be maintained at about 280° C. for about 20 minutes.

At the third temperature, the second zinc precursor may react with the second sulfur precursor to form a shell SH including ZnS. In an aspect, the shell SH including ZnS is formed after the forming of the intermediate layer ML via the in-situ process, and thus a full width at half maximum of the quantum dot QD-C may not increase, and quantum yield may not decrease.

Hereinafter, with reference to examples and comparative examples, the quantum dot including the intermediate layer according to an aspect will be specifically described. In addition, the examples shown below are exemplified only for helping the understanding of the present disclosure, and the scope of the present disclosure is not limited thereto.

In Table 2 below, each of the quantum dots according to comparative example and experimental examples differs in the temperature of the in-situ process and the provided amount of the first zinc precursor. The quantum dots according to the comparative example and experimental examples, the core includes a CIGS compound, and the shell includes ZnS. The quantum dot in the experimental example is manufactured by the following method. Comparative example quantum dot is manufactured in the same manner as the quantum dots according to the experimental examples except that the forming of the intermediate layer is not performed, and the cooling and purification is performed prior to the forming of the shell.

The quantum dot may be manufactured by the forming of a preliminary core (or core), the forming of the intermediate layer, and the forming of the shell. In the forming of the preliminary core (or core), a copper precursor, an indium precursor, a gallium precursor, oleylamine, and 1-octadecene were mixed, treated for about 30 minutes under vacuum, and then transferred to a N₂ atmosphere. Thereafter, S-oleylamine and 1-dodecanethiol were provided in the mixture, heated to about 300° C., and then the reaction was carried out for about 20 minutes to form a preliminary core.

In the forming of the intermediate layer, the preliminary core was cooled at about 140° C., the first zinc precursor was dissolved in tri-n-octylphosphine and provided to the preliminary core. After the providing of the first zinc precursor, the reaction was performed at the second temperature for about 20 minutes to form a preliminary quantum dot. The second temperature is the same temperature as described in Table 2 below. Next, the cooling and purification of the preliminary quantum dot were performed.

In the forming of the shell, tri-n-octylamine was put in a flask, treated for about 30 minutes under vacuum, and then maintained under a N₂ atmosphere. In the flask, the preliminary quantum dot, a second zinc precursor, a second sulfur precursor, and HF were further put, an unnecessary solvent was removed using a vacuum pump, and then the resultant was maintained under a N₂ atmosphere. Next, the obtained was heated to about 280° C., the reaction was performed for about 20 minutes to form a shell, and the obtained was subject to cooling and purification.

The following Table 1 shows the provided materials and amounts thereof during the manufacturing of a quantum dot. Table 1, HF was provided by being dissolved in water such that a weight of HF is about 48 wt % with respect to the total weight of 100 wt % of water and HF.

TABLE 1

| Forming preliminary core | | Forming intermediate layer | | Forming shell | |
|---|---|---|---|---|---|
| | Provided | | Provided | | Provided |
| Materials | amounts | Materials | amount | Materials | amount |
| Copper precursor | 0.005 mmol | Tri-n- | 0.25 ml | Tri-n- | 15 ml |
| Indium precursor | 0.02 mmol | octylphosphine | | octylamine | |
| Gallium | 0.0325 mmol | Zinc chloride | First | Zinc oleate | 1.92 mmol |
| precursor | | | provided | | |
| Oleylamine | 5 ml | | amount | | |
| 1-octadecene | 10 ml | | | HF in Water | 167 μl |
| S-oleylamine | 10 mmol | | | (48 wt %) | |
| 1-dodecanethiol | 50 mmol | | | TOP-S | 1.92 mmol |

In Table 1, S-oleylamine and 1-dodecanethiol are the first sulfur precursor. Zinc chloride is the first zinc precursor, and first provided amounts are the same as described in Table 2 below. Zinc oleate and TOP-S are respectively the second zinc precursor and the second sulfur precursor.

Table 2 below shows measured photoluminescence (PL) wavelength, PL full width at half maximum, and quantum yield (QY) of each quantum dot according to comparative example and experimental examples. The PL wavelength, PL full width at half maximum, and QY were measured using QE-2100 (product of Otsuka Ltd.). In Table 2, the second temperature is a temperature of the in-situ process. In Table 2, the quantum dot according to Comparative Example C-1 is a quantum dot that includes no intermediate layer.

TABLE 2

| | | | PL full | | | |
|---|---|---|---|---|---|---|
| | | | width at | | | |
| | | PL | half | | Second | First provided |
| | | wavelength | maximum | QY | temperature | amount |
| Comparative | C-1 | 620 nm | 50 nm | 90% | — | — |
| Example | | | | | | |
| Experimental | C-2 | 619 nm | 54 nm | 65% | 280° C. | 1.6 mmol |
| Example | C-3 | 620 nm | 53 nm | 78% | 280° C. | 0.25 mmol |
| | E-1 | 620 nm | 49 nm | 80% | 280° C. | 0.13 mmol |
| | C-4 | 620 nm | 51 nm | 82% | 260° C. | 0.25 mmol |
| | E-2 | 624 nm | 49 nm | 83% | 260° C. | 0.13 mmol |
| | C-5 | 616 nm | 50 nm | 83% | 240° C. | 2.4 mmol |
| | C-6 | 618 nm | 50 nm | 80% | 240° C. | 1.6 mmol |
| | E-3 | 623 nm | 49 nm | 81% | 240° C. | 1.2 mmol |
| | C-7 | 622 nm | 50 nm | 82% | 220° C. | 2.4 mmol |
| | E-4 | 623 nm | 50 nm | 91% | 220° C. | 2.0 mmol |
| | E-5 | 623 nm | 49 nm | 88% | 200° C. | 2.4 mmol |
| | E-6 | 622 nm | 48 nm | 88% | 180° C. | 1.6 mmol |
| | E-7 | 621 nm | 48 nm | 94% | 180° C. | 0.5 mmol |
| | E-8 | 623 nm | 47 nm | 91% | 180° C. | 0.25 mmol |
| | E-9 | 620 nm | 46 nm | 95% | 160° C. | 1.6 mmol |
| | E-10 | 623 nm | 45 nm | 95% | 160° C. | 0.25 mmol |
| | E-11 | 626 nm | 44 nm | 95% | 160° C. | 0.13 mmol |
| | E-12 | 626 nm | 44 nm | 95% | 140° C. | 0.13 mmol |
| | E-13 | 626 nm | 44 nm | 95% | 20° C. | 0.5 mmol |

Referring to Table 2, it can be seen that the quantum dots according to Experimental Examples E-1 to E-3, E-5 to E-13 have the full width at half maximum of less than about 50 nm. In addition, it can be seen that each of the quantum dots according to Experimental Examples E-1 to E-13 has quantum yield of about 80% or more. As described above, the quantum dots according to Experimental Examples E-1 to E-13 are quantum dots including an intermediate layer formed via the in-situ process by providing the first zinc precursor. Therefore, in an embodiment, it can be seen that the quantum dot including the intermediate layer formed via the in-situ process emits light having excellent color purity and exhibits excellent light efficiency.

Unlike the quantum dots according to Experimental Examples E-1 to E-13, the quantum dot according to Comparative Example C-1 was not subjected to the in-situ process, and thus no intermediate layer has been formed. The quantum dot according to Comparative Example C-1 includes no intermediate layer and includes a core and a shell covering the core. Therefore, the quantum dot, according to Comparative Example C-1 exhibits a full width at half maximum of about 50 nm. It can be seen that as compared to the quantum dot according to Comparative Example C-1, the quantum dot according to Experimental Example E-4 exhibits high quantum yield.

The quantum dots according to Experimental Examples C-2, C-3, and E-1 were subjected to the in-situ process at the same second temperature, but each quantum dot differs in the provided amount of the first zinc precursor. The quantum dots according to Experimental Examples C-4, and E-2 were subjected to the in-situ process at the same second temperature, but each quantum dot differs in the provided amount of the first zinc precursor. The quantum dots according to Experimental Examples C-5, C-6, and E-3 were subjected to the in-situ process at the same second temperature, but each quantum dot differs in the provided amount of the first zinc precursor. The quantum dots according to Experimental Examples C-7, and E-4 were subjected to the in-situ process at the same second temperature, but each quantum dot differs in the provided amount of the first zinc precursor. From the data in Table 2, it can be seen that, in the case of the same second temperature, as a smaller provided amount of the first zinc precursor, a narrower full width at half maximum and/or higher quantum yield are exhibited.

In each of the quantum dots according to Experimental Examples C-2, C-6, E-6, and E-9, the provided amount of the first zinc precursor is the same, but the second temperature varies. From the data in Table 2, it can be seen that when the provided amount of the first zinc precursor is the same, as the second temperature is lower, the narrower full width at half maximum is exhibited. As the second temperature is lower, the first zinc precursor may be mildly treated, and the core surface may be less damaged, and thus as the second temperature is lower, the quantum dot having a narrower full width at half maximum may be formed.

The quantum dots according to Experimental Examples E-11, and E-12 have the same provided amount of the first zinc precursor, but differ in the second temperature. Since the second temperature is below a certain temperature (for example, below about 160° C.), the formed quantum dot may be saturated to have the full width at half maximum and the quantum yield in a good level.

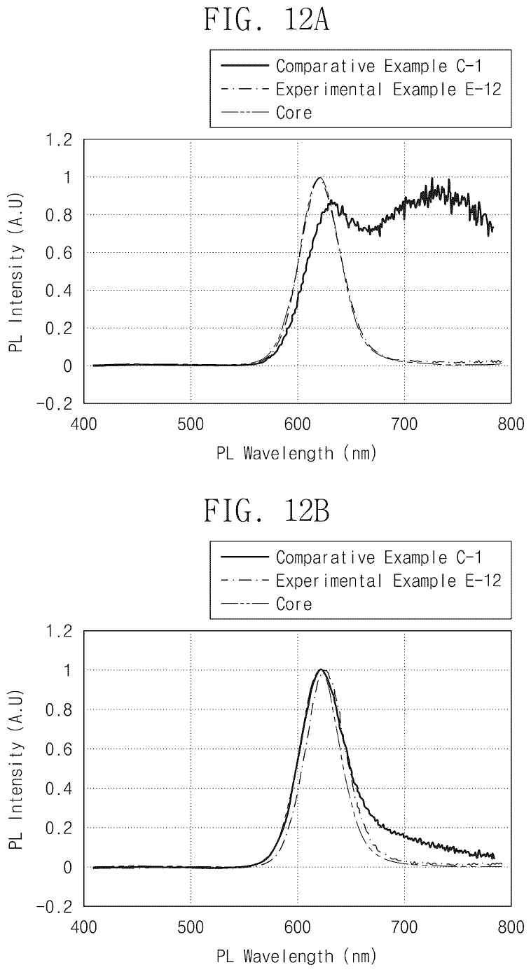

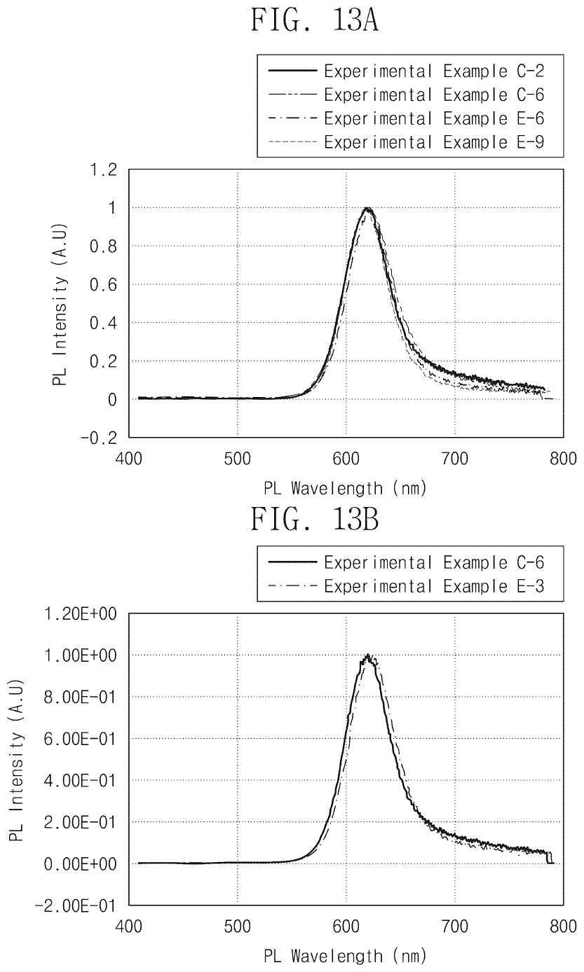

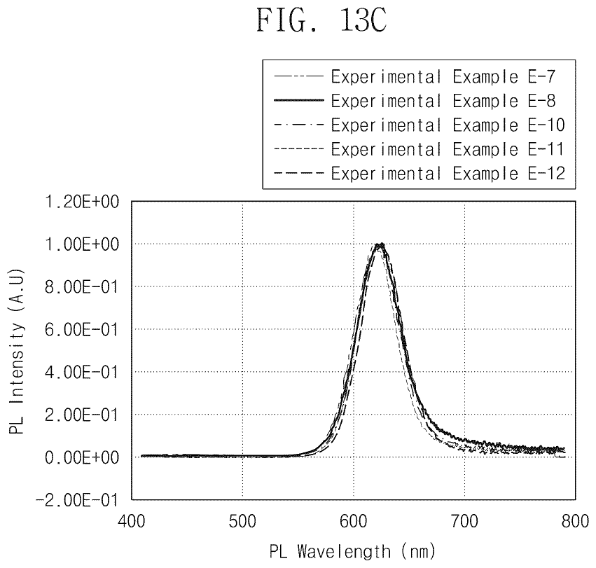

FIG. 12A to FIG. 13C are graphs of PL spectra on the quantum dots according to Comparative Example and Experimental Examples, described with respect to Table 2. Measurements of the PL spectrum were performed with QE-2100 (manufactured by Otsuka).

FIG. 12A and FIG. 12B are graphs showing PL spectra of the quantum dots according to Comparative Example C-1, and Experimental Example E-12. FIG. 12A shows PL spectra of Comparative Example C-1 and Experimental Example E-12, which were measured immediately after reaching about 280° C., before the shell formation was completed. The PL spectra in FIG. 12B are measured in a state after completion of each shell forming of the quantum dots according to Comparative Example C-1, and Experimental Example E-12. The PL spectra in FIG. 12A and FIG. 12B show PL intensity depending on PL wavelengths, and the PL intensity is shown as a relative value (A.U: arbitrary unit).

Referring to FIG. 12A, it can be seen that the quantum dot according to Comparative Example C-1 exhibits a broad spectrum in a long wavelength region of longer than about 600 nm, which has a significant difference from the spectrum of the core. This corresponds to a general trap emission type, and appears when an element on the core surface is lost or a lattice is deformed, and thus a defect such as a dangling bond is present. It can be seen that the quantum dot according to Experimental Example E-12 exhibits a PL spectrum in a similar level to the core. As described above, since the quantum dot according to Comparative Example C-1 was not subjected to the in-situ process, in the quantum dot, no intermediate layer has been formed. Since the quantum dot according to Experimental Example E-12 was subjected to the in-situ process, the intermediate layer has been formed. In the quantum dot according to Experimental Example E-12, the first zinc precursor is mildly treated, and thus it can be seen that a surface of the core is protected without damage.

Referring to FIG. 12B, it can be seen that the quantum dot according to Comparative Example C-1 has a broadened full width at half maximum after forming the shell. Unlike this, the quantum dot according to Experimental Example E-12 has a full width at half maximum maintained in a similar level to the core. In the quantum dot according to Experimental Example E-12, the intermediate layer is formed by performing the in-situ process, and it can be seen that a narrow full width at half maximum is exhibited after the forming of the shell including ZnS.

FIG. 13A to FIG. 13C each shows the PL spectrum on the quantum dot in which the forming of the shell is completed. FIG. 13A shows PL spectra on the quantum dots according to Experimental Examples C-2, C-6, E-6, and E-9. As described above, in each of the quantum dots according to Experimental Examples C-2, C-6, E-6, and E-9, the provided amount of the first zinc precursor is the same, but the temperature in the in-situ process (that is, the second temperature) varies. With reference to FIG. 13A, it can be seen that, as the temperature in the in-situ process is lower, a narrower full width at half maximum is exhibited.

FIG. 13B shows measured PL spectra on the quantum dots according to Experimental Examples C-6 and E-3. As described above, the quantum dots according to Experimental Examples C-6 and E-3 were subjected to the in-situ process at the same second temperature, but the provided amounts of the first zinc precursor vary. Referring to FIG. 13B, when the temperature of the in-situ process (that is, the second temperature) thereof is the same, it can be seen that, the smaller provided amount of the first zinc precursor, the narrower full width at half maximum.

FIG. 13C shows measured spectra on the quantum dots according to Experimental Examples E-7, E-8, E-10, E-11, and E-12. As described in Table 2, in an order of the quantum dots according to Experimental Examples E-7, E-8, E-10, E-11, and E-12, the second temperature decreases, or the provided amounts of the first zinc precursor decreases. Referring to FIG. 13C, it can be seen that the lower second temperature, or more reduced provided amount of the first zinc precursor, the narrower full width at half maximum.

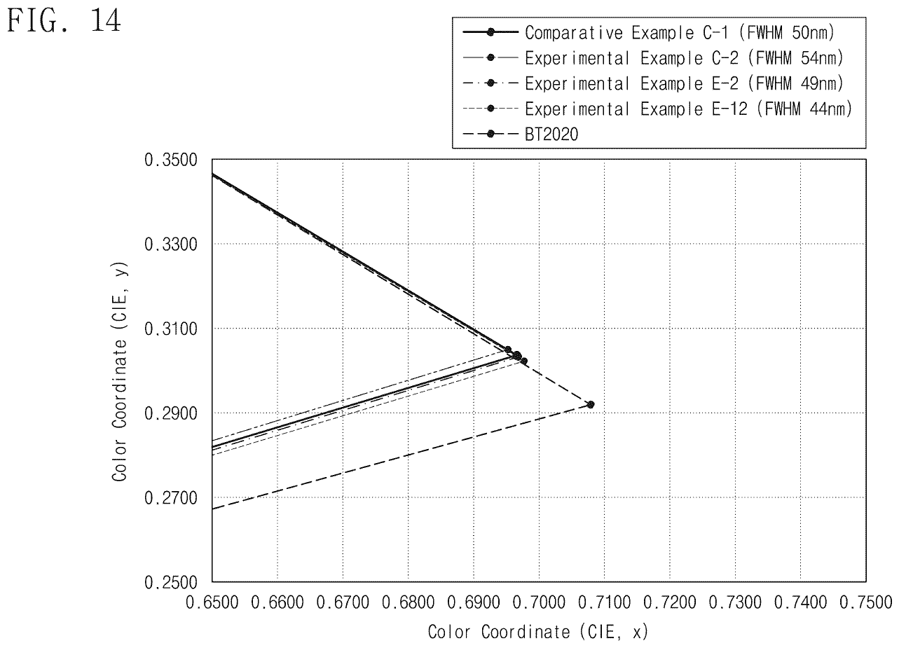

FIG. 14 shows color coordinates of the quantum dots according to Comparative Example C-1, and Experimental Examples C-2, E-2, and E-12. In FIG. 14, a horizontal axis is a CIE color coordinate x, and a vertical axis is a CIE color coordinate y. The CIE color coordinate is CIE 1931. Table 3 below shows a full width at half maximum and a BT.2020 color coordinate matching rate of each of the quantum dots according to Comparative Example C-1, and Experimental Examples C-2, E-2, and E-12. If the color coordinate matching rate is about 92% or more, the quantum dot is determined to be excellent.

TABLE 3

| | Full width at half | color coordinate |
|---|---|---|
| | maximum | matching rate |
| Experimental | 54 nm | 91.4% |
| Example C-2 | | |
| Comparative | 50 nm | 91.9% |
| Example C-1 | | |
| Experimental | 49 nm | 92.0% |
| Example E-2 | | |
| Experimental | 44 nm | 92.3% |
| Example E-12 | | |

Referring to Table 3, each of the quantum dots according to Experimental Example E-2 and E-12 has a full width at half maximum of less than about 50 nm, ad exhibits an excellent color coordinate matching rate. It can be seen that the quantum dots according to Comparative Example C-1, and Experimental Example C-2, having the full width at half maximum of about 50 nm or more, exhibit the low color coordinate matching rate. Therefore, it can be seen that the quantum dot according to an aspect having the full width at half maximum of less than about 50 nm may contribute to improvements in display quality of an electronic apparatus.

The method for manufacturing a light-emitting element according to an aspect may include the forming of the emission layer by providing the quantum dot. The quantum dot may include the core, the intermediate layer covering the core, and the shell covering the intermediate layer. The intermediate layer may be formed by: forming a preliminary core including a CIGS compound; and providing the first zinc precursor through an in-situ process. Thereafter, the shell including ZnS may be formed. The quantum dot including the intermediate layer formed through the in-situ process between the core that includes the CIGS compound and the shell that includes ZnS may exhibit the full width at half minimum of less than about 50 nm and the quantum yield of about 80% or more, and may exhibit excellent material stability for ultraviolet ray. Therefore, the light-emitting element according to an aspect may exhibit excellent processability. The light-emitting element formed using the method for manufacturing a light-emitting element according to an aspect may emit light with high color purity and exhibit excellent element efficiency. The electronic apparatus including the light-emitting element according to an embodiment may exhibit excellent display quality.

The method for manufacturing a light-emitting element according to an aspect may exhibit excellent processability by including the provision of an intermediate layer formed by an in-situ process and a quantum dot including the same.

The light-emitting element according to an aspect, and the electronic apparatus including the same, includes a quantum dot which includes an intermediate layer between a core and a shell, and thus light with excellent color purity may be emitted, and excellent display quality may be exhibited.

Hitherto, although the aspects of the present disclosure have been described, those skilled in the art or having ordinary knowledge of the art will understand that various modifications and changes can be made without departing from the technical idea or features of the present disclosure as described later in the claims.

Accordingly, the technical scope of the present disclosure is not limited to what is set forth in the detailed description of the specification, but should be defined by the claims.

What is claimed is:

1. A method for manufacturing a light-emitting element, the method comprising:
preparing a first electrode;
forming an emission layer on the first electrode, wherein the emission layer comprises a quantum dot that comprises a core, an intermediate layer covering the core, and a shell covering the intermediate layer;
forming a second electrode on the emission layer;
forming a hole transport region; and
forming an electron transport region,
wherein one of the forming of the hole transport region and the forming of the electron transport region is performed between the preparing of the first electrode and the forming of the emission layer, and the other one is performed between the forming of the emission layer and the forming of the second electrode,
wherein the core comprises a multicomponent-based compound comprising Cu, In, Ga, and S,
wherein the intermediate layer comprises Zn,
wherein the quantum dot is formed by a method for manufacturing a quantum dot, the method for manufacturing the quantum dot comprising:
preparing a first mixture comprising a copper precursor, an indium precursor, and a gallium precursor;
adding a first sulfur precursor to the first mixture to form a preliminary core at a first temperature;
cooling the preliminary core at a second temperature, wherein the second temperature is less than the first temperature;
adding a first zinc precursor to the preliminary core to form a preliminary quantum dot including the core and the intermediate layer at the second temperature; and
forming the shell covering the intermediate layer,
wherein the intermediate layer is formed using an in-situ process.

2. The method for manufacturing the light-emitting element of claim 1, wherein the shell comprises ZnS.

3. The method for manufacturing the light-emitting element of claim 1, wherein the second temperature is from about 20° C. to about 280° C.

4. The method for manufacturing the light-emitting element of claim 1, wherein the second temperature is from about 260° C. to about 280° C., and a number of moles of the first zinc precursor is from about 0.01 times to about 4 times a number of moles of the gallium precursor.

5. The method for manufacturing the light-emitting element of claim 1, wherein the second temperature is greater than about 200° C. and less than about 260° C., and a number of moles of the first zinc precursor is greater than about 4 times and less than or equal to about 36.90 times a number of moles of the gallium precursor.

6. The method for manufacturing the light-emitting element of claim 1, wherein the second temperature is from about 20° C. to about 200° C., and a number of moles of the first zinc precursor is from about 0.01 times to about 73.90 times a number of moles of the gallium precursor.

7. The method for manufacturing the light-emitting element of claim 1, wherein the first zinc precursor comprises at least one of dimethyl zinc, diethyl zinc, zinc acetate, zinc acetylacetonate, zinc iodide, zinc bromide, zinc chloride, zinc fluoride, zinc oleate, zinc carbonate, zinc cyanide, zinc nitrate, zinc oxide, zinc peroxide, zinc perchlorate, zinc sulfate, or zinc carboxylate.

8. The method for manufacturing the light-emitting element of claim 1, wherein the first temperature is from about 230° C. to about 330° C.

9. The method for manufacturing the light-emitting element of claim 1, wherein the first mixture further comprises at least one of oleylamine, 1-octadecene, octadecane, methanethiol, ethanethiol, propanethiol, butanethiol, pentanethiol, hexanethiol, octanethiol, hexadecanethiol, benzylthiol, methane amine, ethane amine, propane amine, butylamine, pentylamine, hexylamine, octylamine, dodecylamine, hexadecylamine, octadecylamine, dimethylamine, diethylamine, dipropylamine, trioctylamine, methanoic acid, ethanoic acid, propanoic acid, buthanoic acid, pentanoic acid, hexanoic acid, heptanoic acid, octanoic acid, dodecanoic acid, hexadecanoic acid, octadecanoic acid, oleic acid, benzoic acid, trimethyl phosphine, methyldiphenyl phosphine, triethyl phosphine, ethyldiphenyl phosphine, trioctyl phosphine, trimethyl phosphine oxide, methyldiphenyl phosphine oxide, triethyl phosphine oxide, ethyldiphenyl phosphine oxide, or trioctyl phosphine oxide.

10. The method for manufacturing the light-emitting element of claim 1, wherein the first sulfur precursor comprises at least one of S-oleylamine, 1-dodecanethiol, trioctylphosphine-sulfur (TOP-S), S-tributylphosphine (S-TBP), S-triphenylphosphine (S-TPP), S-trioctylamine (S-TOA), S-octadecene (S-ODE), S-diphenylphosphine (S-DPP), S-dodecylamine, octanethiol, octadecanethiol, α-toluenethiol, allyl mercaptan, or bis(trimethylsilyl) sulfide.

11. The method for manufacturing the light-emitting element of claim 1, wherein the forming of the shell covering the intermediate layer comprises:
preparing a solvent containing tri-n-octylamine;
adding the preliminary quantum dot, a second zinc precursor, and a second sulfur precursor to the solvent to form a second mixture; and
heating the second mixture to a third temperature to form the shell covering the intermediate layer.

12. The method for manufacturing the light-emitting element of claim 1, wherein the quantum dot has a full width at half maximum (FWHM) of less than about 50 nm, and wherein the quantum dot has a quantum yield of about 80% or greater.

13. The method for manufacturing the light-emitting element of claim 1, wherein the intermediate layer further comprises sulfur derived from the first sulfur precursor.

14. A light-emitting element comprising:
a first electrode;
an emission layer comprising a quantum dot, wherein the quantum dot comprises a core, an intermediate layer covering the core, and a shell covering the intermediate layer;
a second electrode;
a hole transport region between the first electrode and the second electrode; and
an electron transport region between the first electrode and the second electrode,
wherein the emission layer is between the hole transport region and the electron transport region, and
wherein the core comprises a multicomponent-based compound comprising Cu, In, Ga, and S,
wherein the intermediate layer comprises Zn, and
wherein the shell comprises ZnS.

15. The light-emitting element of claim 14, wherein the quantum dot has a full width at half maximum (FWHM) of less than about 50 nm, and wherein the quantum dot has a quantum yield of about 80% or more.

16. The light-emitting element of claim 14, wherein the shell has a thickness from about 0.1 nm to about 2 nm.

17. The light-emitting element of claim 14, wherein the shell further comprises at least one of SiO₂, Al₂O₃, TiO₂, ZnO, MnO, Mn₂O₃, Mn₃O₄, CuO, FeO, Fe₂O₃, Fe₃O₄, CoO, Co₃O₄, NiO, MgAl₂O₄, CoFe₂O₄, NiFe₂O₄, CoMn₂O₄, ZnSe, ZnTe, ZnSeS, ZnTeS, ZnGaS, GaAs, GaP, GaS, GaSe, AgGaS, AgGaS₂, GaSb, HgS, HgSe, HgTe, InAs, InP, InGaP, InSb, AlAs, AlP, or AlSb.

18. An electronic apparatus comprising a display module configured to provide an image,
wherein the display module comprises a base layer, a circuit layer disposed on the base layer, and a display element layer disposed on the circuit layer, the display element layer comprising a light-emitting element,
wherein the light-emitting element comprises:
a first electrode;
an emission layer comprising a quantum dot, wherein the quantum dot comprises a core, an intermediate layer covering the core, and a shell covering the intermediate layer;
a second electrode;
a hole transport region between the first electrode and the second electrode; and
an electron transport region between the first electrode and the second electrode, and
wherein the emission layer is between the hole transport region and the electron transport region,
wherein the core comprises a multicomponent-based compound including Cu, In, Ga, and S,
wherein the intermediate layer comprises Zn, and
wherein the shell comprises ZnS.

19. The electronic apparatus of claim 18, wherein the quantum dot has a full width half maximum (FWHM) of less than about 50 nm, and wherein the quantum dot has a quantum yield of about 80% or more.

20. The electronic apparatus of claim 18, wherein the shell further comprises at least one of SiO₂, Al₂O₃, TiO₂, ZnO, MnO, Mn₂O₃, Mn₃O₄, CuO, FeO, Fe₂O₃, Fe₃O₄, CoO, Co₃O₄, NiO, MgAl₂O₄, CoFe₂O₄, NiFe₂O₄, CoMn₂O₄, ZnSe, ZnTe, ZnSeS, ZnTeS, ZnGaS, GaAs, GaP, GaS, GaSe, AgGaS, AgGaS₂, GaSb, HgS, HgSe, HgTe, InAs, InP, InGaP, InSb, AlAs, AlP, or AlSb.
